(19) United States
(12) Patent Application Publication
(10) Pub. No.: US 2024/0332170 A1
(43) Pub. Date: Oct. 3, 2024

(54) INDUCTOR EMBEDDED IN A SUBSTRATE OF A SEMICONDUCTOR DEVICE

(71) Applicant: Taiwan Semiconductor Manufacturing Company, Ltd., Hsinchu (TW)

(72) Inventors: Chien Hung LIU, Hsinchu County (TW); Harry-HakLay CHUANG, Zhubei City (TW); Kuo-Ching HUANG, Hsinchu City (TW); Yu-Sheng CHEN, Taoyuan City (TW); Yi Ching ONG, Hsinchu (TW); Yu-Jui WU, Hsinchu (TW)

(21) Appl. No.: 18/194,193

(22) Filed: Mar. 31, 2023

(51) Int. Cl. H01L 23/522; H01F 17/00; H01F 17/06

(52) U.S. Cl. CPC H01L 23/5227; H01F 17/0033; H01F 17/06; H01L 23/5226; H01L 28/10

(57) ABSTRACT

Some implementations described herein provide an inductor device formed in a substrate of a semiconductor device including an integrated circuit device. The inductor device may use one or more conduction layers that are included in the substrate. Furthermore, the inductor device may be electrically coupled to the integrated circuit device. By forming the inductor device in the substrate of the semiconductor device, an electrical circuit including the inductor device and the integrated circuit device may be formed within a single semiconductor device.

### BACKGROUND

Various semiconductor device packing techniques may be used to incorporate one or more semiconductor dies into a semiconductor die package. In some cases, semiconductor dies may be stacked in a semiconductor die package to achieve a smaller horizontal or lateral footprint of the semiconductor die package and/or to increase the density of the semiconductor die package. Semiconductor device packing techniques that may be performed to integrate a plurality of semiconductor dies in a semiconductor die package may include integrated fanout (InFO), package on package (POP), chip on wafer (CoW), wafer on wafer (WoW), and/or chip on wafer on substrate (CoWoS), among other examples.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIGS. 2A and 2B are diagrams of example voltage regulator circuits including an inductor described herein.

FIGS. 3A-3D are diagrams of example implementations of an example semiconductor die package described herein.

FIGS. 4A-4H are diagrams of an example implementation of forming a semiconductor die package described herein.

FIGS. 5A and 5B are diagrams of example implementations of an example semiconductor die package described herein.

FIGS. 6A-6D are diagrams of example implementations of an example solenoid inductor structure described herein.

FIGS. 7A-7D are diagrams of example implementations of a circuit including an example solenoid inductor structure described herein.

FIG. 8 is a diagram including an example transient response of a semiconductor die package including the solenoid inductor structure described herein.

FIG. 9 is a diagram of example components of one or more devices of FIG. 1 described herein.

FIG. 10 is a flowchart of an example process associated with forming a semiconductor die package described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, an electrical circuit includes a combination of devices. For example, the electrical circuit may include a voltage regulator device and an inductor device. The voltage regulator device may be included as part of a semiconductor device, and the inductor device may be included as part of a discrete device that is distinct and separate from the semiconductor device. In such a case, and due to a length of an electrical path between the inductor device and the voltage regulator device, a performance of the electrical circuit (e.g., a parasitic resistance and/or a transient response) may not satisfy a threshold. Additionally, or alternatively, a design characteristic of the electrical circuit (e.g., a consumption of space due to the discrete device in combination with the semiconductor device) may not satisfy a sizing threshold.

Some implementations described herein provide an inductor device formed in a substrate of a semiconductor device including an integrated circuit device. The inductor device may use one or more conduction layers that are included in the substrate. Furthermore, the inductor device may be electrically coupled to the integrated circuit device. By forming the inductor device in the substrate of the semiconductor device, an electrical circuit including the inductor device and the integrated circuit device may be formed within a single semiconductor device. Additionally, or alternatively, a design characteristic of the electrical circuit (e.g., a consumption of space due to the discrete device in combination with the semiconductor device) may not satisfy a sizing threshold.

In this way, and relative to an implementation of the electrical circuit that uses a discrete inductor device, a length of an electrical path between the inductor device and the integrated circuit device may be reduced to increase a performance of the electrical circuit. Additionally, or alternatively, the inclusion of the inductor device within the semiconductor device may eliminate a need for a separate semiconductor die package (for the discrete inductor device) to reduce an amount of resources used to form the electrical circuit (semiconductor processing tools, raw materials, manpower, and/or computing resources, among other examples).

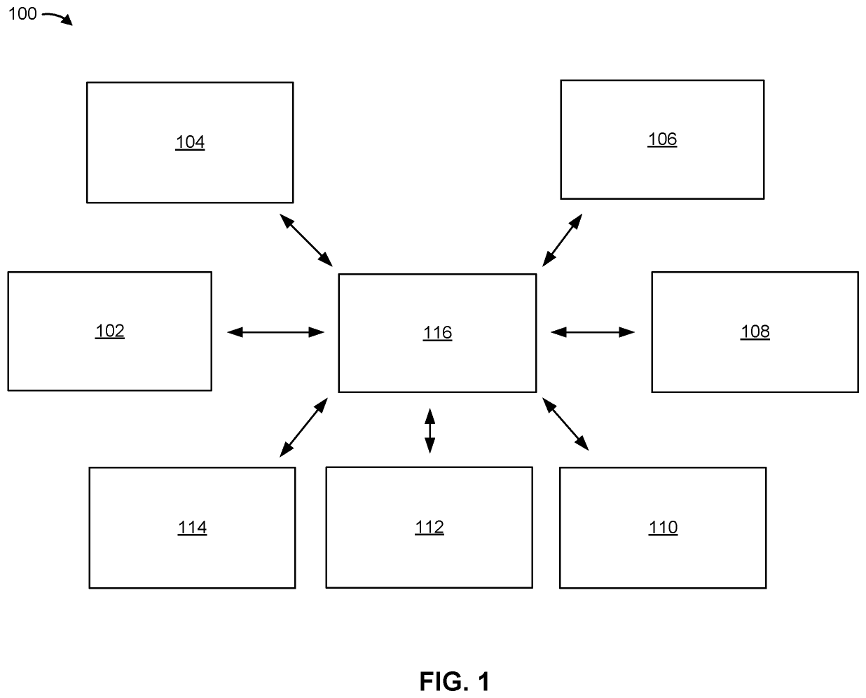

FIG. 1 is a diagram of an example environment 100 in which systems and/or methods described herein may be implemented. As shown in FIG. 1, the example environment 100 may include a plurality of semiconductor processing tools 102-114 and a wafer/die transport tool 116. The plurality of semiconductor processing tools 102-112 may include a deposition tool 102, an exposure tool 104, a developer tool 106, an etch tool 108, a planarization tool 110, a plating tool 112, a bonding tool 114, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, a low-pressure CVD (LPCVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the deposition tool 102 includes an epitaxial tool that is configured to form layers and/or regions of a device by epitaxial growth. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The bonding tool 114 is a semiconductor processing tool that is capable of bonding two or more work pieces (e.g., two or more semiconductor substrates, two or more semiconductor devices, two or more semiconductor dies) together. For example, the bonding tool 114 may include a direct bonding tool. A direct bonding tool is a type of bonding tool that is configured to bond semiconductor dies together directly through copper-to-copper (or other direct metal) connections. As another example, the bonding tool 114 may include a eutectic bonding tool that is capable of forming a eutectic bond between two or more wafers together. In these examples, the bonding tool 114 may heat the two or more wafers to form a eutectic system between the materials of the two or more wafers.

Wafer/die transport tool 116 includes a mobile robot, a robot arm, a tram or rail car, an overhead hoist transport (OHT) system, an automated materially handling system (AMHS), and/or another type of device that is configured to transport substrates and/or semiconductor devices between semiconductor processing tools 102-114, that is configured to transport substrates and/or semiconductor devices between processing chambers of the same semiconductor processing tool, and/or that is configured to transport substrates and/or semiconductor devices to and from other locations such as a wafer rack, a storage room, and/or the like. In some implementations, wafer/die transport tool 116 may be a programmed device that is configured to travel a particular path and/or may operate semi-autonomously or autonomously. In some implementations, the example environment 100 includes a plurality of wafer/die transport tools 116.

For example, the wafer/die transport tool 116 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 116 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations). In these implementations, the wafer/die transport tool 116 is configured to transport substrates and/or semiconductor devices between the processing chambers of the deposition tool 102 without breaking or removing a vacuum (or an at least partial vacuum) between the processing chambers and/or between processing operations in the deposition tool 102.

In some implementations, one or more of the semiconductor processing tools 102-114 and/or the wafer/die transport tool 116 may perform a series of semiconductor processing operations described herein. The series of semiconductor processing operations includes etching two or more first cavities through a backside of a silicon substrate of a semiconductor die to expose conductive layers in an interconnect region of the semiconductor die. The series of semiconductor processing operations includes depositing a first conductive material in the two or more first cavities to form two or more backside through silicon via structures that connect to the conductive layers. The series of semiconductor processing operations includes depositing one or more dielectric redistribution layers of a redistribution region on the backside of the silicon substrate. The series of semiconductor processing operations includes etching two or more second cavities through the one or more dielectric redistribution layers to expose the two or more backside through silicon via structures. The series of semiconductor processing operations includes depositing a second conductive material that fills the two or more second cavities and electrically couples the two or more backside through silicon via structures to form and inductor.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

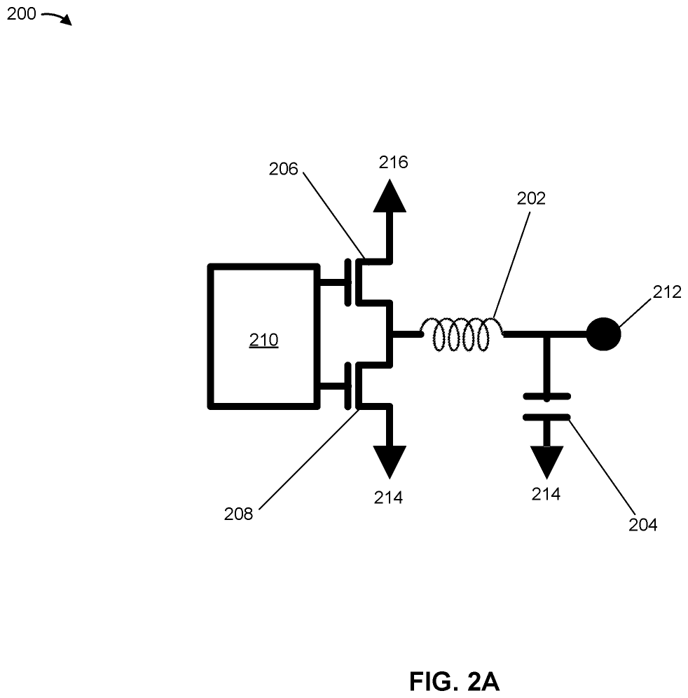

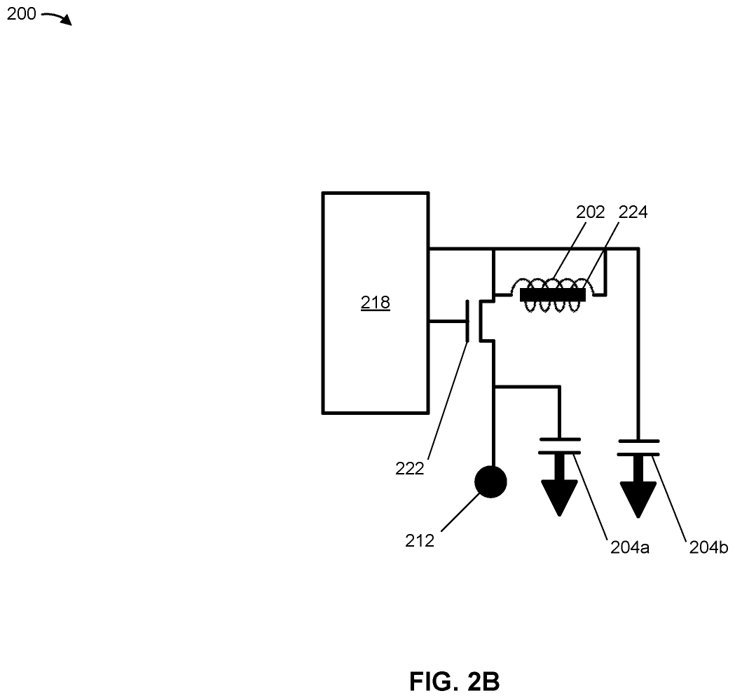

FIGS. 2A and 2B include implementations of example voltage regulator circuits 200 including an inductor described herein. FIGS. 2A and 2B may correspond to implementations of voltage regulator circuits that may be included in a semiconductor die package described herein.

In FIG. 2A, the voltage regulator circuit may include an example of a synchronous buck converter, which is a type of switched mode power converter. The voltage regulator circuit 200 may be included as part of a power supply circuit, a battery charging circuit, and/or another type of circuit in which direct current to direct current (DC:DC) conversion (e.g., a step-down conversion or a step-up conversion) may be provided by the voltage regulator circuit 200.

As shown in FIG. 2, the voltage regulator circuit 200 may include an inductor 202 (e.g., an output inductor of the voltage regulator circuit 200), a capacitor 204 (e.g., output capacitor of the voltage regulator circuit 200), a plurality of transistors such as a high-side transistor 206 and a low-side transistor 208, and a pulse width modulation (PWM) circuit 210, among other examples.

The inductor 202 and the capacitor 204 may be electrically connected in series as an inductor-capacitor (LC) filter of the voltage regulator circuit 200. The LC filter may provide current charging and current discharging across a load at an output terminal 212 (e.g., Vout) in a regulated manner. The load may be electrically connected in series with the capacitor 204 at the output terminal 212 and an electrical ground terminal 214.

The high-side transistor 206 and the low-side transistor 208 may each include a bipolar junction transistor (BJT), a field effect transistor (FET), a metal oxide semiconductor FET (MOSFET), and/or another type of transistor. The high-side transistor 206 and the low-side transistor 208 may be electrically connected in series. A first source/drain terminal of the high-side transistor 206 may be electrically connected to an input terminal 216, which is electrically connected to a voltage supply. A second source/drain terminal of the high-side transistor 206 may be electrically connected to a first source/drain terminal of the low-side transistor 208 and to a terminal of the inductor 202. A first source/drain terminal of the low-side transistor 208 may be electrically connected to the second source/drain terminal of the high-side transistor 206 and to the terminal of the inductor 202. A second source/drain terminal of the low-side transistor 208 may be electrically connected to an electrical ground terminal 214.

The gate terminals of the high-side transistor 206 and the low-side transistor 208 may each be electrically connected with the PWM circuit 210. The PWM circuit 210 may include electrical circuitry that is configured to synchronize the switching operation of the high-side transistor 206 and the low-side transistor 208 to enable the voltage regulator circuit 200 to provide a regulated output voltage to the load.

In operation, during which the high-side transistor 206 is switched on by the PWM circuit 210, an electrical current is supplied to the load at the output terminal 212 through the high-side transistor 206. The low-side transistor 208 is switched off, which enables charging of the LC filter of the voltage regulator circuit 200. When the PWM circuit 210 switches the high-side transistor 206 off and the low-side transistor 208 on, the LC filter is discharged through the output terminal 212.

In FIG. 2B, the voltage regulator circuit includes logic circuitry 218 and a switch device 222. In some implementations, the switch device 222 corresponds to a transistor device. Additionally, and as shown in FIG. 2B, the voltage regulator circuit 200 includes capacitors 204a and 204b. In some implementations, capacitor 204a corresponds to a deep trench capacitor. Additionally, or alternatively and in some implementations, capacitor 204b corresponds to a deep trench capacitor.

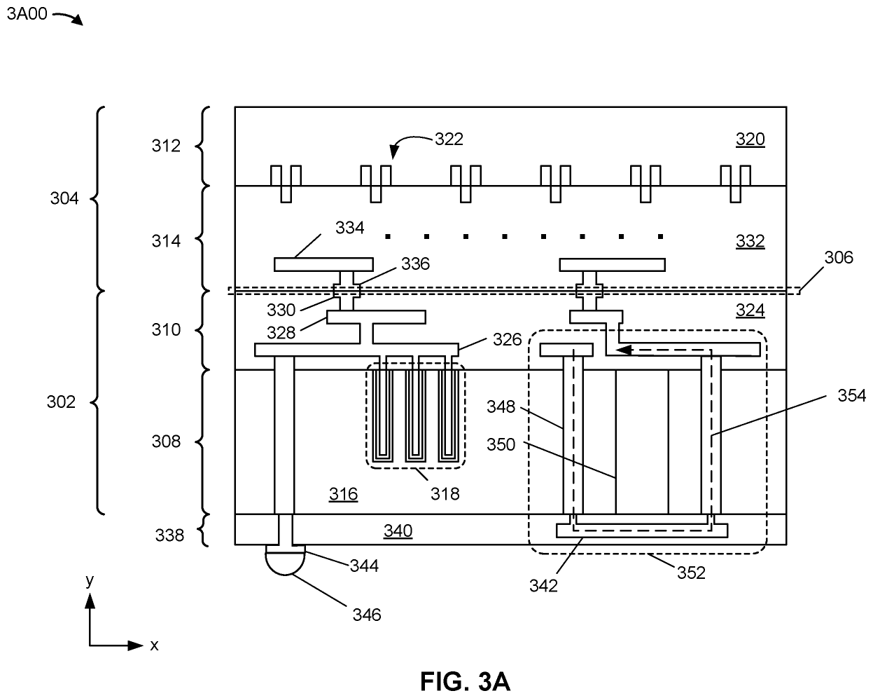

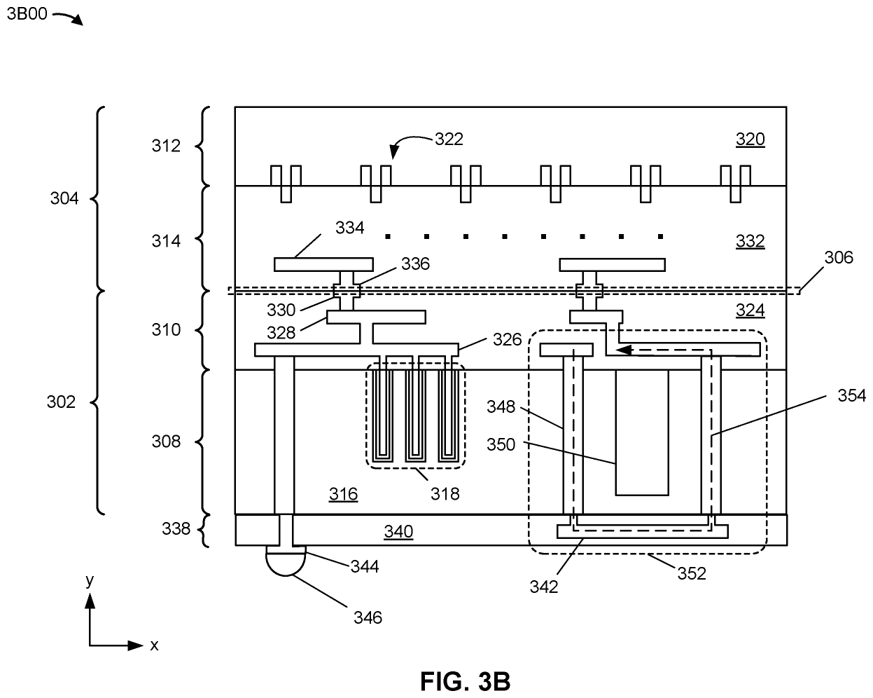

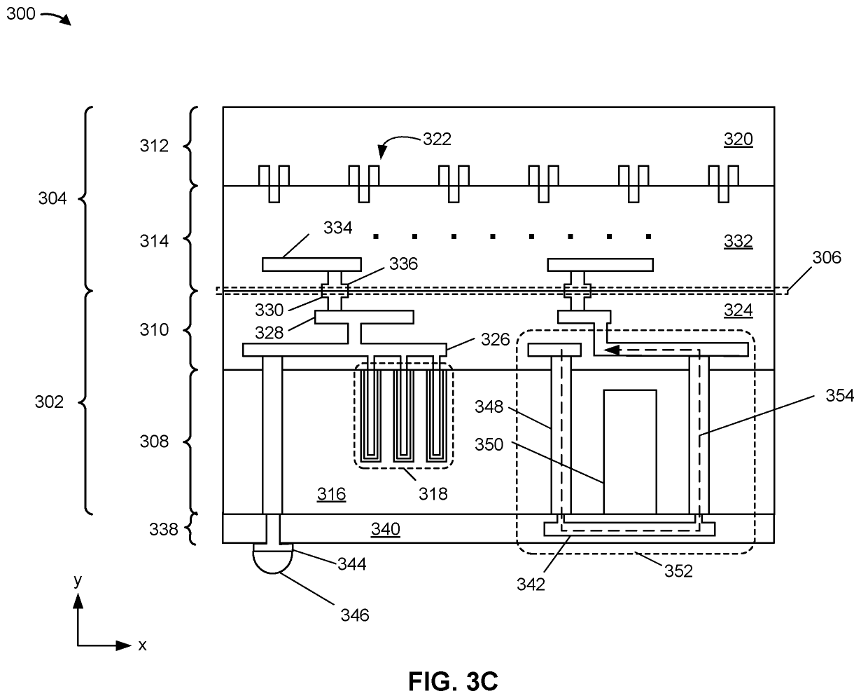

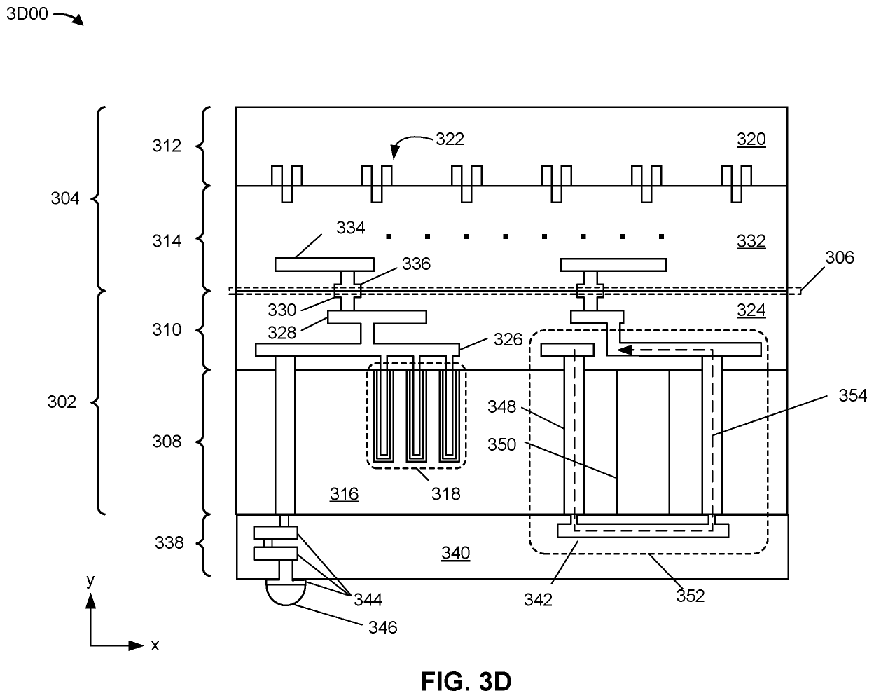

The voltage regulator circuit of FIG. 2B further includes the inductor 202. In some implementations, and as described in greater detail in connection with FIGS. 3-10 and elsewhere herein, the inductor 202 may correspond to a solenoid inductor structure. In some implementations, the inductor includes a magnetic core 224.

As indicated above, FIGS. 2A and 2B are provided as examples. Other examples may differ from what is described with regard to FIGS. 2A and 2B.

FIGS. 3A-3D are diagrams of example implementations of an example semiconductor die package 300 described herein. The semiconductor die package 300 includes an example of a wafer on wafer (WoW) semiconductor die package, a chip on wafer (CoW) semiconductor die package, a die to die direct bonded semiconductor die package, or another type of semiconductor die package in which semiconductor dies are directly bonded and vertically arranged or stacked.

As shown in FIG. 3A, the semiconductor die package 300 includes a first semiconductor die 302 and a second semiconductor die 304. In some implementations, the semiconductor die package 300 includes additional semiconductor dies. The first semiconductor die 302 may include an inductor-capacitor (LC) semiconductor die, which is a type of semiconductor die that includes a combination of inductor structures and capacitor structures that correspond to an inductor 202 and a capacitor 204 of a voltage regulator circuit 200 included in the semiconductor die package 300. The second semiconductor die 304 may include a logic semiconductor die, such as a system on chip (SoC) die, a central processing unit (CPU) die, a graphics processing unit (GPU) die, a digital signal processing (DSP) die, and/or an application specific integrated circuit (ASIC) die, among other examples. Additionally, or alternatively, the first semiconductor die 302 may include a memory die, an input/output (I/O) die, a pixel sensor die, and/or another type of semiconductor die. A memory die may include a static random access memory (SRAM) die, a dynamic random access memory (DRAM) die, a NAND die, a high bandwidth memory (HBM) die, and/or another type of memory die.

The first semiconductor die 302 and the second semiconductor die 304 may be joined together (e.g., directly bonded) at a bonding interface 306. In some implementations, one or more layers may be included between the first semiconductor die 302 and the second semiconductor die 304 at the bonding interface 306, such as one or more passivation layers, one or more bonding films, and/or one or more layers of another type.

The first semiconductor die 302 may include a device region 308 (e.g., a substrate region) and an interconnect region 310 adjacent to and/or above the device region 308. In some implementations, the first semiconductor die 302 may include additional regions. Similarly, the second semiconductor die 304 may include a device region 312 and an interconnect region 314 adjacent to and/or below the device region 312. In some implementations, the second semiconductor die 304 may include additional regions. The first semiconductor die 302 and the second semiconductor die 304 may be bonded at the interconnect region 310 and the interconnect region 314. The bonding interface 306 may be located at a first side of the interconnect region 314 facing the interconnect region 310 and corresponding to a first side of the second semiconductor die 304.

The device region 308 may be formed in or on a substrate 316. The substrate 316 may correspond to a silicon (Si) substrate, a substrate formed of a material including silicon, a III-V compound semiconductor material substrate such as gallium arsenide (GaAs), a silicon on insulator (SOI) substrate, a germanium substrate (Ge), a silicon germanium (SiGe) substrate, a silicon carbide (SiC) substrate, or another type of semiconductor substrate.

The device region 308 may include one or more other components of the voltage regulator circuit 200. For example, a trench capacitor structure 318 may be included in the device region 308 of the first semiconductor die 302. The trench capacitor structure 318 may correspond to a capacitor 204 of the LC filter of the voltage regulator circuit 200. Liners may be included between the trench capacitor structure 318 and the substrate of the device region 308 to prevent electron migration into the device region 308, to prevent metal diffusion into the device region 308, and/or to promote adhesion between the device region 308 and the trench capacitor structure 318.

The device region 312 may be formed in or on a substrate 320. The substrate 320 may correspond to a silicon (Si) substrate, a substrate formed of a material including silicon, a III-V compound semiconductor material substrate such as gallium arsenide (GaAs), a silicon on insulator (SOI) substrate, a germanium substrate (Ge), a silicon germanium (SiGe) substrate, a silicon carbide (SiC) substrate, or another type of semiconductor substrate.

The device region 312 may include one or more integrated circuit devices 322 included in the semiconductor substrate of the device region 312. The integrated circuit devices 322 may include one or more semiconductor transistor structures (e.g., planar transistor structures, fin field effect transistor (FinFET) transistor structures, nanosheet transistor structures (e.g., gate all around (GAA) transistor structures), memory cells, pixel sensors, controller circuits, logic circuitry, and/or other types of semiconductor devices. In some implementations, at least a subset of the integrated circuit devices 322 may be included in a voltage regulator circuit 200 of the semiconductor die package 300. For example, an integrated circuit device 322 may correspond to a high-side transistor 206 of the voltage regulator circuit 200, another integrated circuit device 322 may correspond to a low-side transistor 208 of the voltage regulator circuit 200, and one or more other integrated circuit devices 322 may correspond to a PWM circuit 210 of the voltage regulator circuit 200. The voltage regulator circuit 200 may be configured to provide voltage regulation for other integrated circuit devices 322 of the second semiconductor die 304.

The interconnect regions 310 and 314 may be referred to as back end of line (BEOL) regions. The interconnect region 310 may include one or more dielectric layers 324, which may include a silicon nitride (SiNₓ), an oxide (e.g., a silicon oxide (SiOₓ) and/or another oxide material), a low dielectric constant (low-k) dielectric material, and/or another type of dielectric material. In some implementations, one or more etch stop layers (ESLs) may be included in between layers of the one or more dielectric layers 324. The one or more ESLs may include aluminum oxide (Al₂O₃), aluminum nitride (AlN), silicon nitride (SiN), silicon oxynitride (SiOₓN_{y}), aluminum oxynitride (AlON), and/or a silicon oxide (SiOₓ), among other examples.

The interconnect region 310 may further include metallization layers 326 and 328 in the one or more dielectric layers 324. The trench capacitor structure(s) 318 in the device region 308 may be electrically connected and/or physically connected with the metallization layer 326. The metallization layers 326 and 328 may include conductive lines, trenches, vias, pillars, interconnects, and/or another type of metallization layers.

Contacts 330 may be included in the one or more dielectric layers 324 of the interconnect region 310. The contacts 330 may be electrically connected and/or physically connected with one or more of the metallization layers 328. The contacts 330 may include conductive terminals, conductive pads, conductive pillars, and/or another type of contacts. The metallization layers 326, the metallization layers 328, and the contacts 330 may each include one or more conductive materials, such as copper (Cu), gold (Au), silver (Ag), nickel (Ni), tin (Sn), ruthenium (Ru), cobalt (Co), tungsten (W), titanium (Ti), one or more metals, one or more metal alloys, one or more conductive ceramics, and/or another type of conductive materials.

The interconnect region 314 may include one or more dielectric layers 332, which may include a silicon nitride (SiNₓ), an oxide (e.g., a silicon oxide (SiOₓ) and/or another oxide material), a low dielectric constant (low-k) dielectric material, and/or another type of dielectric material. In some implementations, one or more etch stop layers (ESLs) may be included in between layers of the one or more dielectric layers 332. The one or more ESLs may include aluminum oxide (Al₂O₃), aluminum nitride (AlN), silicon nitride (SiN), silicon oxynitride (SiOₓN_{y}), aluminum oxynitride (AlON), and/or a silicon oxide (SiOₓ), among other examples.

The interconnect region 314 may further include metallization layers 334 in the one or more dielectric layers 332. The metallization layers 334 may include conductive lines, trenches, vias, pillars, interconnects, and/or another type of metallization layers. In some implementations, the metallization layers 334 are connected to the integrated circuit devices 322 in the device region 312.

Contacts 336 may be included in the one or more dielectric layers 332 of the interconnect region 314. The contacts 336 may be electrically connected and/or physically connected with one or more of the metallization layers 334.

The contacts 336 may include conductive terminals, conductive pads, conductive pillars, and/or another type of contacts. The metallization layers 334 and the contacts 336 may each include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive materials.

In some implementations, and as shown in FIG. 3A, the contacts 336 and the contacts 330 join (e.g., bond) within the bonding interface 306. In such implementations, the contacts 336 and 330 provide electrical connectivity between the metallization layers 328 and 334. In some implementations, the bonding interface includes metal-to-metal and dielectric-to-dielectric bonds. In such implementations, the contacts 330 and 336, and respective surfaces of the one or more dielectric layers 332 and 334, may be joined through a eutectic bonding process. Further, and in such implementations, joining of the contacts 330 and 336 may correspond to metal-to-metal bonds.

As further shown in FIG. 3A, the semiconductor die package 300 may include a redistribution region 338. The redistribution region 338 may include a redistribution layer (RDL) structure and/or another type of redistribution region. The redistribution region 338 may be configured to fan out and/or route signals and I/O of the semiconductor dies 302 and 304.

The redistribution region 338 may include one or more dielectric layers 340 and one or more metallization layers 342 disposed in the one or more dielectric layers 340. The one or more dielectric layers 340 may include a silicon nitride (SiNₓ), an oxide (e.g., a silicon oxide (SiOₓ) and/or another oxide material), a low dielectric constant (low-k) dielectric material, and/or another suitable dielectric material.

The one or more metallization layers 342 of the redistribution region 338 may include one or more materials such as a gold (Au) material, a copper (Cu) material, a silver (Ag) material, a nickel (Ni) material, a tin (Sn) material, and/or a palladium (Pd) material, among other examples. The one or more metallization layers 342 of the redistribution region 338 may include metal lines, vias, interconnects, and/or another type of metallization layers.

An under bump metal (UBM) layer 344 may be included on a top surface of the one or more dielectric layers 340 of the redistribution region 338. The UBM layer 344 may be electrically connected and/or physically connected with one or more metallization layers 342 in the redistribution region 338. The UBM layer 344 may be included in recesses in the top surface of the one or more dielectric layers 340. The UBM layer 344 may include one or more conductive materials, such as copper (Cu), gold (Au), silver (Ag), nickel (Ni), tin (Sn), ruthenium (Ru), cobalt (Co), tungsten (W), titanium (Ti), one or more metals, one or more metal alloys, one or more conductive ceramics, and/or another type of conductive materials.

As further shown in FIG. 3A, the semiconductor die package 300 may include conductive terminals 346. The conductive terminals 346 may be electrically connected and/or physically connected with the UBM layer 344. The UBM layer 344 may be included to facilitate adhesion to the one or more metallization layers 342 in the redistribution region 338, and/or to provide increased structural rigidity for the conductive terminals 346 (e.g., by increasing the surface area to which the conductive terminals 346 are connected). The conductive terminals 346 may include ball grid array (BGA) balls, land grid array (LGA) pads, pin grid array (PGA) pins, and/or another type of conductive terminals. The conductive terminals 346 may enable the semiconductor die package 300 to be mounted to a circuit board, a socket (e.g., an LGA socket), an interposer or redistribution region of a semiconductor die package (e.g., a chip on wafer on substrate CoWoS package, an integrated fanout (InFO) package), and/or another type of mounting structure.

As further shown in FIG. 3A, the semiconductor die package 300 may include one or more backside through silicon via (BTSV) structures 348 through the device region 308. The one or more BTSV structures 348 may include vertically elongated conductive structures (e.g., conductive pillars, conductive vias) that electrically connect one or more of the metallization layers 326 in the interconnect region 310 of the first semiconductor die 302 to one or more metallization layers 342 in the redistribution region 338. The BTSV structures 348 may be referred to as through silicon via (TSV) structures in that the BTSV structures 348 extend fully through a silicon substrate (e.g., the substrate 316 of the device region 308) as opposed to extending fully through a dielectric layer or an insulator layer. The one or more BTSV structures 348 may include one or more conductive materials, such as copper (Cu), gold (Au), silver (Ag), nickel (Ni), tin (Sn), ruthenium (Ru), cobalt (Co), tungsten (W), titanium (Ti), one or more metals, one or more metal alloys, one or more conductive ceramics, and/or another type of conductive materials.

A magnetic core structure 350 may be between two or more interconnect structures (e.g., of the BTSV structures 348). The magnetic core structure 350 may include one or more magnetic materials, such as an iron (Fe) material, a cobalt (Co) material, a nickel (Ni) material, a cobalt iron (CoFe) alloy material, a nickel cobalt (NiCo) alloy material, a nickel iron (NiFe) alloy material, a nickel cobalt iron (NiCoFe) alloy material, one or more metals, one or more metal alloys, and/or another type of magnetic materials.

In some implementations, the one or more BTSV structures 348, portions of the metallization layers 326, and portions of the metallization layers 342 form a solenoid inductor structure 352. The solenoid inductor structure 352 may correspond to an inductor 202 of the LC filter of the voltage regulator circuit 200.

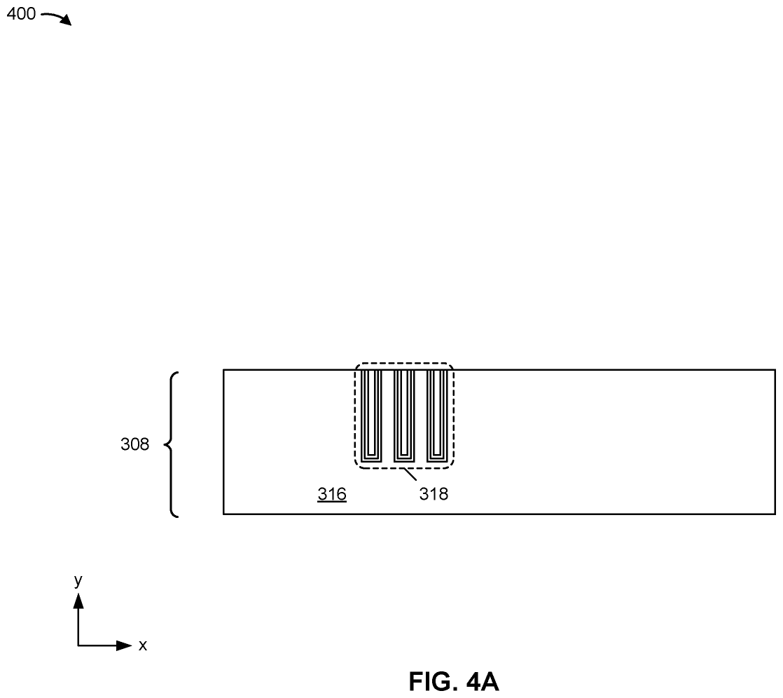

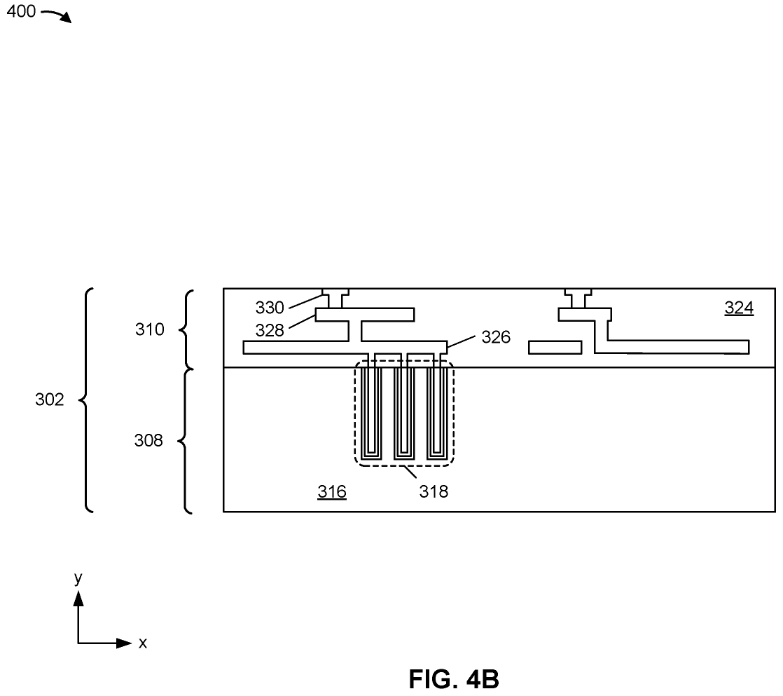

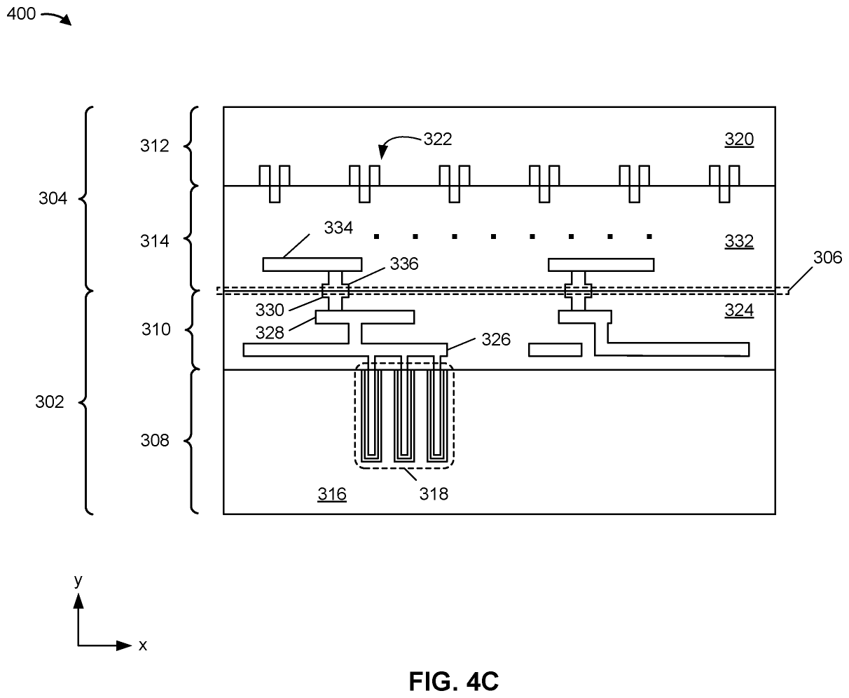

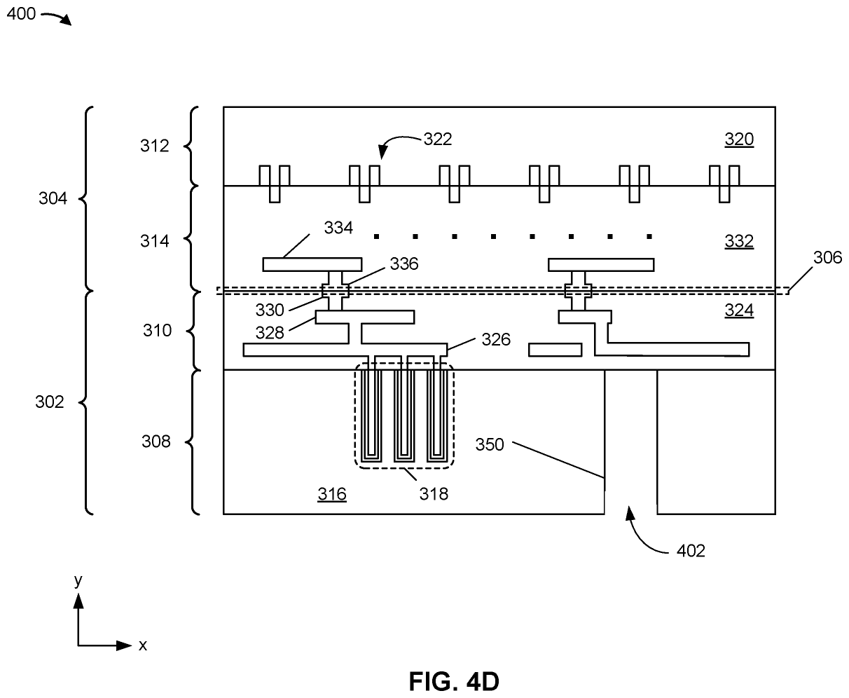

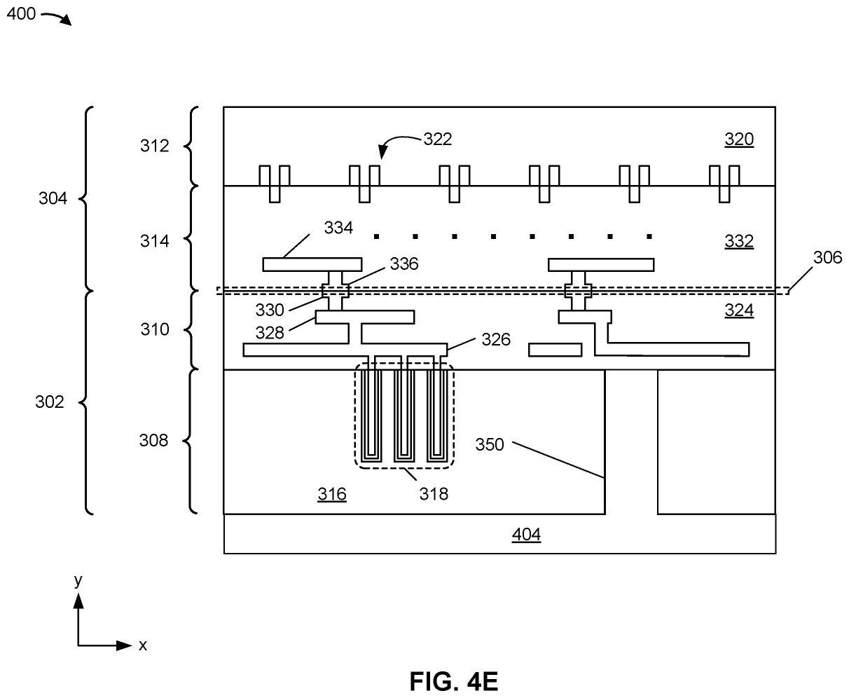

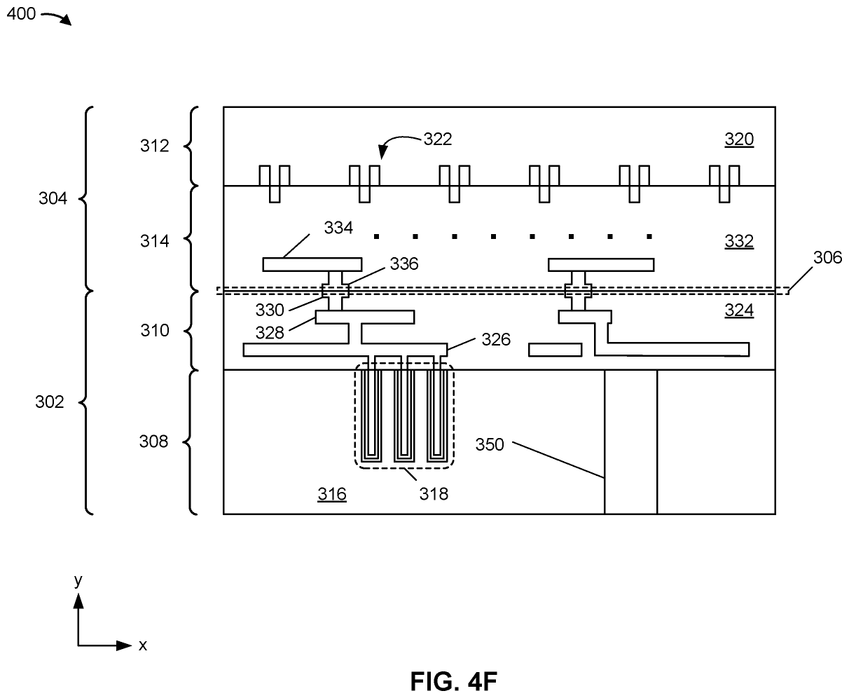

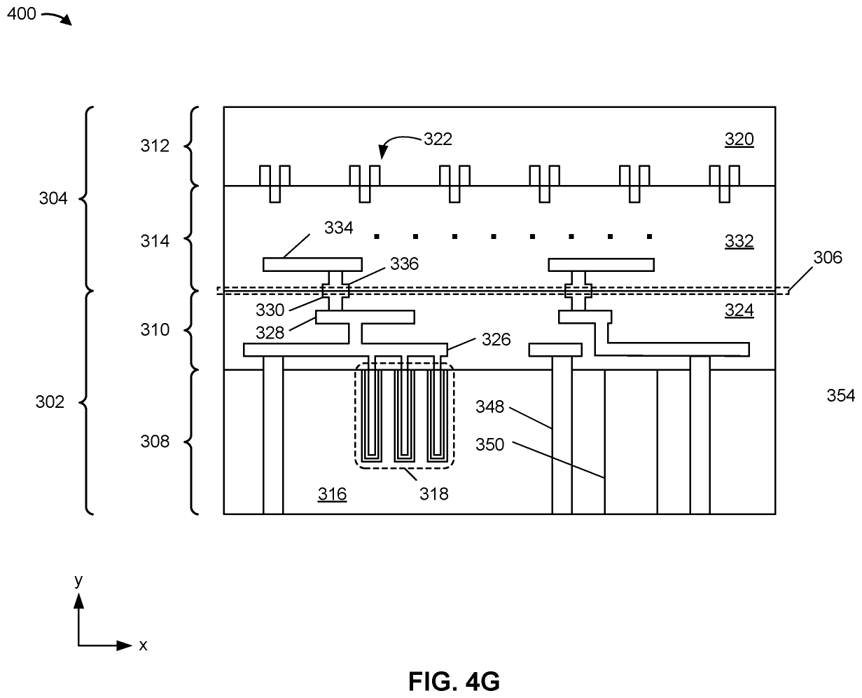

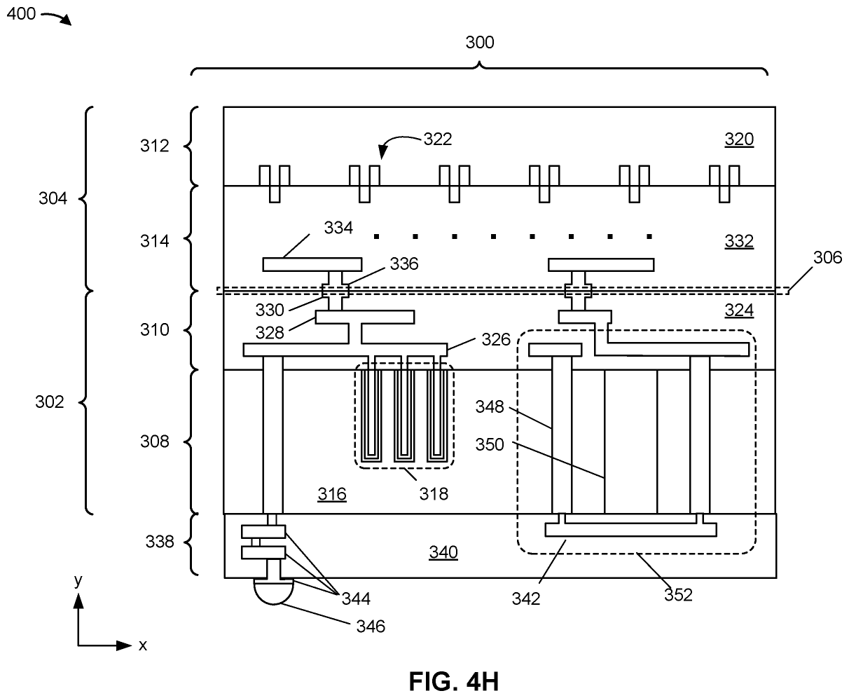

As described in greater detail in connection with FIGS. 4A-8 and elsewhere herein, an electrical current 354 may flow through the solenoid inductor structure 352 to create an inductance in a circuit (e.g., the voltage regulator circuit 200). In some implementations, and as an example, an inductive performance of the solenoid inductor structure 352 is included in a range of approximately 0.1 nanohenrys (nH) to approximately 100 nH. If the inductive performance is less than approximately 0.1 nH, the solenoid inductor structure 352 may be incompatible with a circuit (e.g., the voltage regulator circuit 200) of the semiconductor die package 300. If the inductive performance is greater than approximately 100 nH, the solenoid inductor structure 352 may also be incompatible with a circuit of the semiconductor die package 300. Additionally, or alternatively, if the inductive performance is greater than approximately 100 nH, a size of the solenoid inductor structure 352 may increase to consume real estate of the semiconductor die package 300 and increase a cost of the semiconductor die package 300. However, other values and ranges for the inductive performance are within the scope of the present disclosure.

FIG. 3B show an example implementation of the semiconductor die package 300 in which the magnetic core structure 350 passes partially through the substrate 316. As shown in FIG. 3B, a top surface of the magnetic core structure 350 may be aligned with a top surface of the substrate 316. Such a configuration of the magnetic core structure 350 (e.g., the magnetic core structure 350 passing partially through the substrate 316 with respective, top surfaces aligned) may be implemented to center the magnetic core structure 350 between the metallization layers 326 and 342 to increase a performance of the solenoid inductor structure 352.

FIG. 3C show an example implementation of the semiconductor die package 300 in which the magnetic core structure 350 passes partially through the substrate 316. As shown in FIG. 3C, a bottom surface of the magnetic core structure 350 may be aligned with a bottom surface of the substrate 316. Such a configuration of the magnetic core structure 350 (e.g., the magnetic core structure 350 passing partially through the substrate 316 with respective, bottom surfaces aligned) may be implemented to center the magnetic core structure 350 between the metallization layers 326 and 342 to increase a performance of the solenoid inductor structure 352.

FIG. 3D shows an example implementation of the semiconductor die package 300 in which the UBM layer 344 is distributed across multiple metallization layers within the redistribution region 338. Such a distribution of the UBM layer 344 across the multiple metallization may reduce electrical inductance within the semiconductor die package 300 relative to the UBM layer 344 being distributed across a single layer as shown in FIGS. 3A-3C.

As shown in FIGS. 3A-3D, a semiconductor die package (e.g., the semiconductor die package 300) includes a substrate region (e.g., the substrate 316) including a first side and a second side opposite the first side. The semiconductor die package includes an interconnect region (e.g., the interconnect region 310) over the first side of the substrate region that includes at least one metal layer (e.g., the metallization layer 326). The semiconductor die package includes a redistribution region (e.g., the redistribution region 338) over the second side of the substrate region comprising at least one conductive layer (e.g., the metallization layer 342). The semiconductor die package includes at least two via structures (e.g., the BTSV structures 348) passing through the substrate region connecting the conductive layer in the redistribution region and the at least one metal layer in the interconnect region, where the at least two via structures, the conductive layer, and the metal layer form an inductor (e.g., the solenoid inductor structure 352).

Additionally, or alternatively, the semiconductor die package (e.g., the semiconductor die package 300) includes a first semiconductor die (e.g., the semiconductor die 302) including a substrate region (e.g., the substrate 316), an interconnect region over the substrate region (e.g., the interconnect region 310), a via structure passing through the substrate region (e.g., one of the BTSV structures 348), and an inductor (e.g., the solenoid inductor structure 352) including a portion formed in the substrate region. The semiconductor die package includes a second semiconductor die (e.g., the semiconductor die 304) bonded to the interconnect region of the first semiconductor die.

The number and arrangement of devices shown in FIGS. 3A-3D are provided as one or more examples. In practice, there may be additional devices, fewer devices, different devices, or differently arranged devices than those shown in FIGS. 3A-3D. Furthermore, two or more devices shown in FIGS. 3A-3D may be implemented within a single device, or a single device shown in FIGS. 3A-3D may be implemented as multiple, distributed devices. Additionally, or alternatively, a set of devices (e.g., one or more devices) of FIGS. 3A-3D may perform one or more functions described as being performed by another set of devices of FIGS. 3A-3D.

FIGS. 4A-4H are diagrams of an example implementation 400 of forming a semiconductor die package described herein. In some implementations, the example implementation 400 includes an example process for forming the first semiconductor die 302, the second semiconductor die 304, or portions thereof. In some implementations, one or more of the semiconductor processing tools 102-114 and/or the wafer/die transport tool 116 may perform one or more of the operations described in connection with the example implementation 400. In some implementations, one or more operations described in connection with the example implementation 400 may be performed by another semiconductor processing tool.

Turning to FIG. 4A, the trench capacitor structure 318 is formed as part of the device region 308. For example, one or more of the semiconductor processing tools 102-114 may perform photolithography patterning operations, etching operations, deposition operations, CMP operations, and/or another type of operations to form the trench capacitor structure 318 in the substrate 316.

As shown in FIG. 4B, the dielectric layers 324, the metallization layers 326 and 328, and the contacts 330 are formed as part of the interconnect region 310 (e.g., the interconnect region 310 over the device region). For example, one or more of the semiconductor processing tools 102-114 may perform photolithography patterning operations, etching operations, deposition operations, CMP operations, and/or another type of operations to form the dielectric layers 324, the metallization layers 326 and 328, and the contacts 330 as part of the interconnect region 310.

As shown in FIG. 4C, the second semiconductor die 304 is formed and joined with the first semiconductor die 302. For example, and as part of forming the second semiconductor die 304, one or more of the semiconductor processing tools 102-114 may perform photolithography patterning operations, etching operations, deposition operations, CMP operations, and/or another type of operations to form the device region 312. Such operations may include forming the integrated circuit devices 322 on or within the substrate 316. Additionally, or alternatively, and part of forming the second semiconductor die 304, one or more of the semiconductor processing tools 102-114 may perform photolithography patterning operations, etching operations, deposition operations, CMP operations, and/or another type of operations to form the interconnect region 314. Such operations may include forming dielectric layers 332, the metallization layers 334, and/or the contacts 336. Further, and as shown in FIG. 4C, the bonding tool 114 may join the first semiconductor die 302 and the second semiconductor die 304 at the bonding interface 306.

Turning to FIG. 4D, a cavity 402 is formed in the first semiconductor die 302. For example, one or more of the one or more of the semiconductor processing tools 102-114 may perform photolithography patterning operations, etching operations, and/or another type of operations to form the cavity 402 in the device region 312.

As shown in FIG. 4E, a magnetic layer 404 is formed on the first semiconductor die 302. For example, and as part of forming the first semiconductor die 302, one or more of the semiconductor processing tools 102-114 may perform deposition operations, CMP operations, and/or another type of operations to form the magnetic layer 404 on the first semiconductor die 302. Forming the magnetic layer 404 on the first semiconductor die 302 may include filling the cavity 402 in the device region 308.

FIG. 4F shows formation of the magnetic core structure 350. For example, one or more of the semiconductor processing tools 102-114 may perform etching operations, CMP operations, and/or another type of operations to remove portions on the surface of the first semiconductor die 302 (e.g., excluding other portions filling the cavity 402) of the magnetic layer 404 and form the magnetic core structure 350 in the device region 312.

As shown in FIG. 4G, the BTSV structures 348 are formed through the device region 308 and into the interconnect region 310. For example, one or more of the semiconductor processing tools 102-114 may perform photolithography patterning operations, etching operations, deposition operations, CMP operations, and/or another type of operations as part of forming the BTSV structures 348. For example, and as part of forming the BTSV structures 348, the etch tool 108 may etch two or more cavities through a backside of the silicon substrate 316 to expose the metallization layer 326. Additionally, or alternatively, the deposition tool 102 may deposit a conductive material in the two or more cavities to form the BTSV structures 348 and connect the BTSV structures 348 to one or more of the metallization layers 326 and/or 328.

Turning to FIG. 4H, the redistribution region 338 is formed on the first semiconductor die 302. For example, one or more of the semiconductor processing tools 102-114 may perform photolithography patterning operations, etching operations, deposition operations, CMP operations, and/or another type of operations to form the dielectric layers 340, the one or more metallization layers 342, the UBM layer 344, and the conductive terminals 346. For example, the deposition tool 102 may deposit one or more of the dielectric layers 340 on the backside of the substrate 316 and the etch tool 108 may etch two or more cavities through the one or more of the dielectric layers 340 to expose the BTSV structures 348. Additionally, the deposition tool 102 may deposit the metallization layer 342 that fills the two or more cavities.

The example implementation 400 forms the solenoid inductor structure 352 (e.g., the solenoid inductor structure 352 including portions of the metallization layers 326, the metallization layers 342, and/or the BTSV structures 348) as part of the semiconductor die package 300. In some implementations, the solenoid inductor structure 352 is included in an electrical circuit (e.g., the voltage regulator circuit 200).

Relative to an implementation of an electrical circuit that uses a discrete inductor device, a length of an electrical path between the solenoid inductor structure 352 and an integrated circuit device (e.g., the integrated circuit devices 322) may be reduced to increase a performance of the electrical circuit. Additionally, or alternatively, the inclusion of the solenoid inductor structure 352 within the semiconductor die package 300 may eliminate a need for a separate semiconductor die package (for the discrete inductor device) to reduce an amount of resources used to form the electrical circuit (semiconductor processing tools, raw materials, manpower, and/or computing resources, among other examples).

As indicated above, FIGS. 4A-4H are provided as an example. Other examples may differ from what is described with regard to FIGS. 4A-4H.

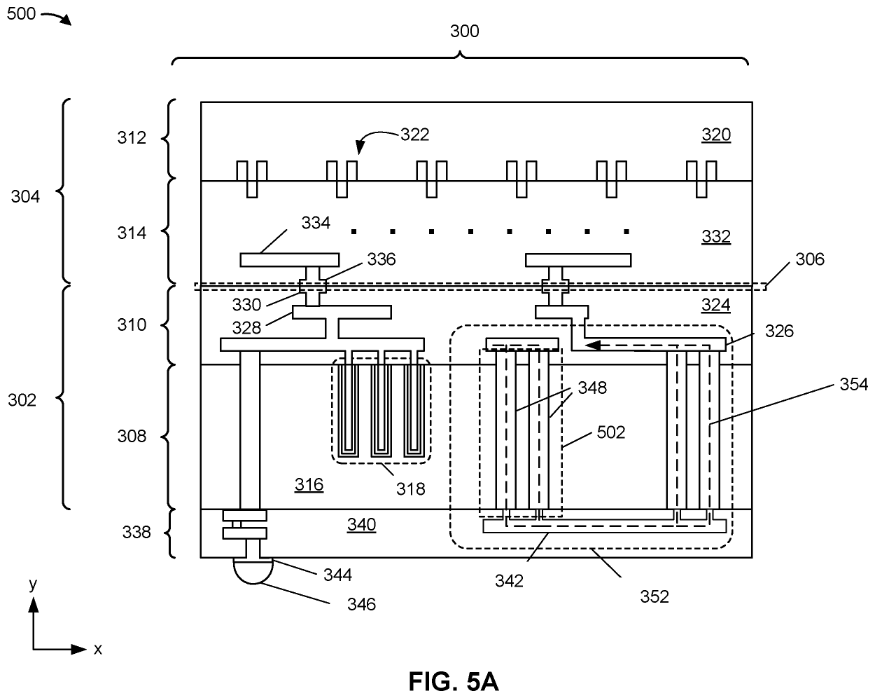

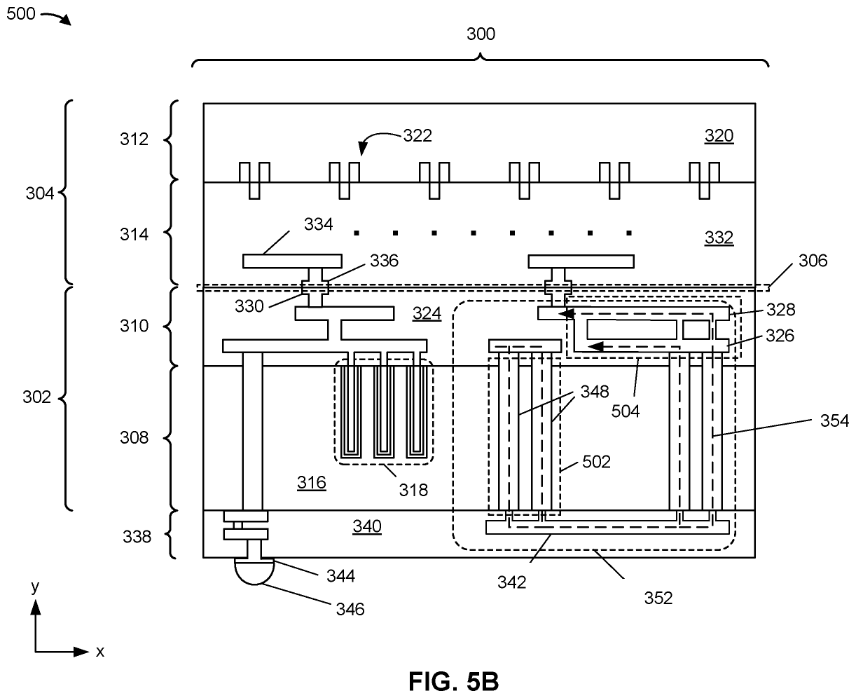

FIGS. 5A and 5B are diagrams of example implementations 500 of an example semiconductor die package described herein. The semiconductor die package may correspond to the semiconductor die package 300. The example implementations 500 include examples of shunting structures that may be included in the solenoid inductor structure 352.

In FIG. 5A, the semiconductor die package 300 includes a shunting structure 502 within the device region 308. As shown, the shunting structure 502 includes interconnect structures of the two or more interconnect structures (e.g., the BTSV structures 348). In FIG. 5A, the shunting structure 502 may divert, divide, or redirect the electrical current 354 within the solenoid inductor structure 352 to tune the solenoid inductor structure 352 and/or prevent power surges within an electrical circuit including the solenoid inductor structure 352 (e.g., the voltage regulator circuit 200).

Turning to FIG. 5B, the semiconductor die package 300 further includes a shunting structure 504 within the interconnect region 310. As shown, the shunting structure 504 includes portions of two or more conductive layers (e.g., portions of the metallization layers 326 and 328) within the interconnect region 310. In FIG. 5B, the shunting structure 504 may further divert, divide, or redirect the electrical current 354 within the solenoid inductor structure 352 to tune the solenoid inductor structure 352 and/or prevent power surges within an electrical circuit including the solenoid inductor structure 352 (e.g., the voltage regulator circuit 200).

As indicated above, FIGS. 5A and 5B are provided as examples. Other examples may differ from what is described with regard to FIGS. 5A and 5B.

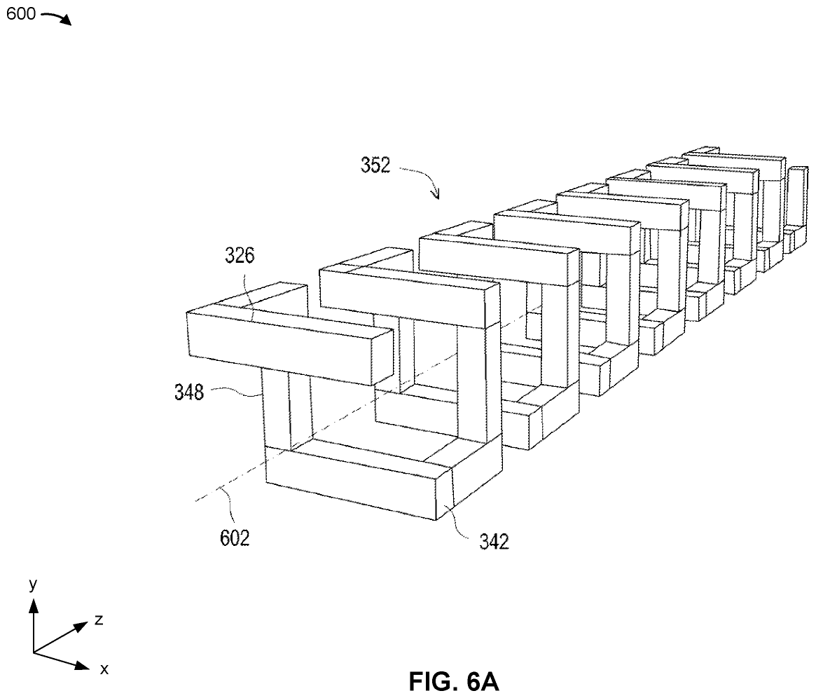

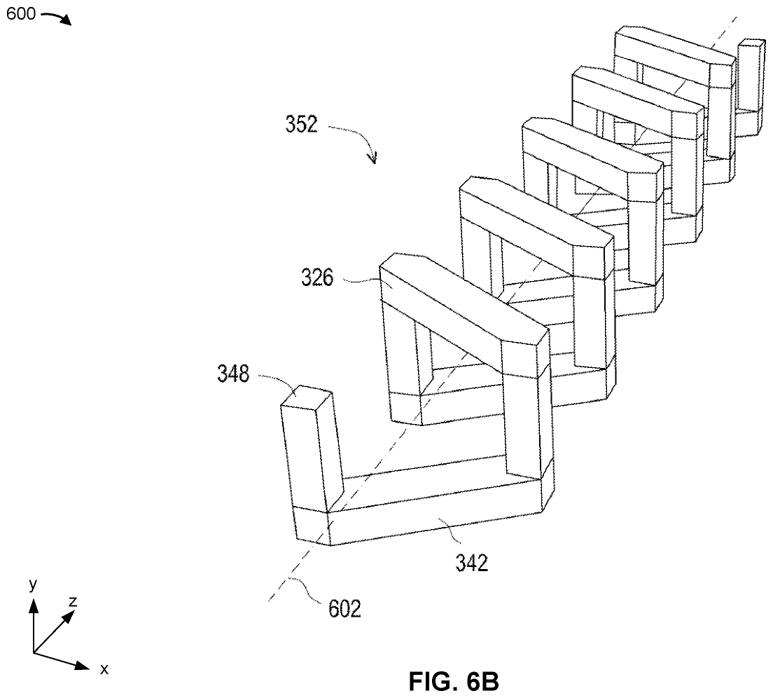

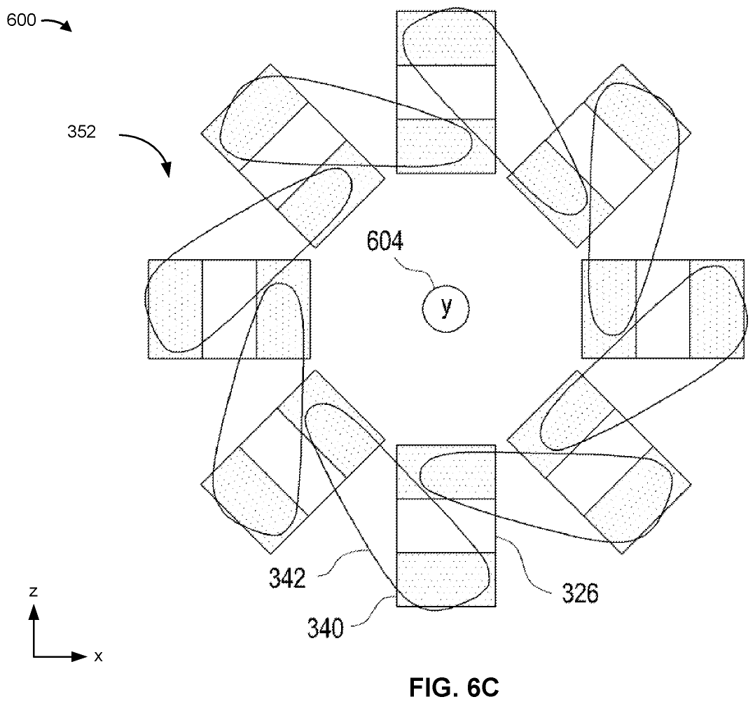

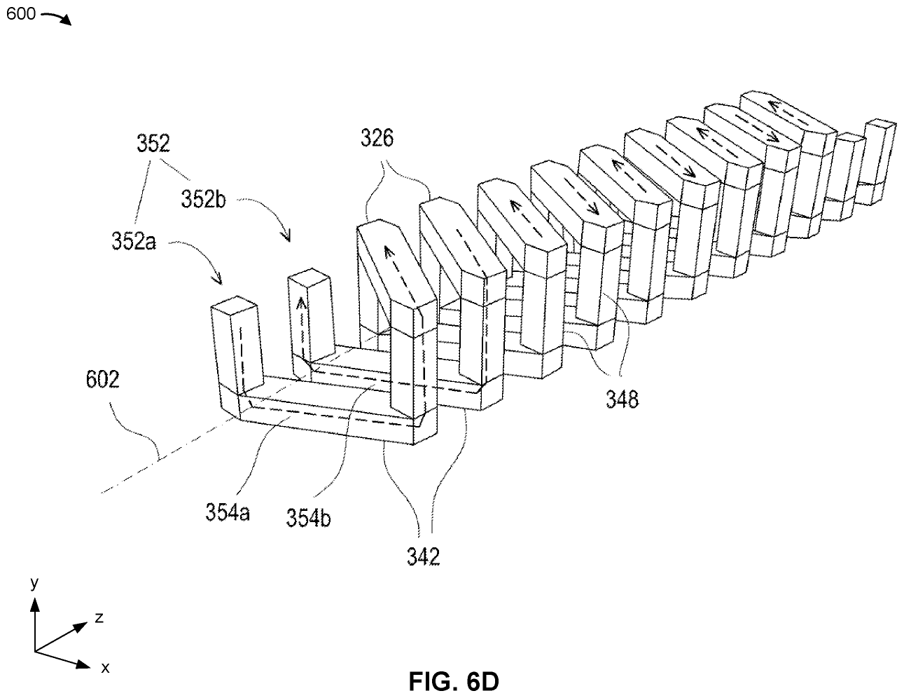

FIGS. 6A-6D are diagrams of example implementations 600 of an example solenoid inductor structure described herein. The solenoid inductor structure may correspond to the solenoid inductor structure 352. The example implementations 600 include examples of configurations and/or layouts of the solenoid inductor structure 352.

As shown in the isometric view of FIG. 6A, the solenoid inductor structure 352 may include multiple segments formed from portions of the metallization layer 326, portions of the metallization layer 342, and two or more of the BTSV structures 348. In FIG. 6A, the multiple segments may be arranged, sequentially, at approximately orthogonal angles and centered about an axis 602. The axis 602 may correspond to an approximately lateral axis within a layered structure (e.g., a layered structure including the interconnect region 310, the device region 308, and the redistribution region 338). As shown in FIG. 6A, the solenoid inductor structure 352 may form an approximately helical shape that is dispersed along the axis 602. Further, the arrangement of the multiple segments (e.g., an approximately helical shaped structure), as shown in FIG. 6A, may be selected to increase a number of coils within the solenoid inductor structure 352 to increase an inductance performance of the solenoid inductor structure 352.

Turning to the isometric view of FIG. 6B, the solenoid inductor structure 352 may include multiple segments formed from portions of the metallization layer 326, portions of the metallization layer 342, and two or more of the BTSV structures 348. In FIG. 6B, upper and lower segments of the solenoid inductor structure 352 (e.g., portions of the metallization layers 326 and 342) are angled (e.g., non-orthogonally) with respect to the axis 602. As shown in FIG. 6B, the solenoid inductor structure 352 may form an approximately helical shape that is dispersed along the axis 602. Further, the arrangement of the multiple segments (e.g., an approximately helical shaped solenoid inductor structure), as shown in FIG. 6B, may be selected to decrease a number of coils within the solenoid inductor structure 352 to decrease an inductance performance of the solenoid inductor structure 352.

As shown in the top view FIG. 6C, the solenoid inductor structure 352 may include multiple segments formed from portions of the metallization layer 326, portions of the metallization layer 342, and two or more of the BTSV structures 348. In FIG. 6C, an arrangement of the multiple segments is centered about an axis 604. The axis 604 may correspond to an approximately vertical axis passing through a layered structure (e.g., a layered structure including the interconnect region 310, the device region 308, and the redistribution region 338). As shown in FIG. 6C, the solenoid inductor structure 352 may be an approximately toroidal shape (e.g., an approximately toroidal shaped structure), that is dispersed along the axis 604. Further, the arrangement of the multiple segments as shown in FIG. 6C, may be selected when an availability of a route for a lateral path within the layered structure is limited.

As shown in the isometric view of FIG. 6D, the solenoid inductor structure 352 includes portions 352a and 352b. Each of the portions 352a and 352b may include multiple segments formed from portions of the metallization layer 326, portions of the metallization layer 342, and two or more of the BTSV structures 348. In FIG. 6D, an arrangement of the multiple segments is centered about the axis 602. As shown in FIG. 6D, the solenoid inductor structure 352 may correspond to an inverse coupled structure that is dispersed along the axis 602. In the solenoid inductor structure 352 of FIG. 6D, the portion 352a (e.g., a first portion) may be configured to conduct the electrical current 354a (e.g., a first electrical current) along a first approximately helical path in a first direction. Further, in the solenoid inductor structure 352 of FIG. 6D, the portion 352b (e.g., a second portion) may be configured to conduct the electrical current 354b (e.g., a second electrical current) along a second approximately helical path in a second direction that is opposite the first direction. Further, the arrangement of the portions 352a and 352b including the multiple segments (e.g., an inverse coupled solenoid inductor structure), as shown in FIG. 6D, may be selected to increase a transient response of the solenoid inductor structure 352.

As indicated above, FIGS. 6A-6D are provided as examples. Other examples may differ from what is described with regard to FIGS. 6A-6D.

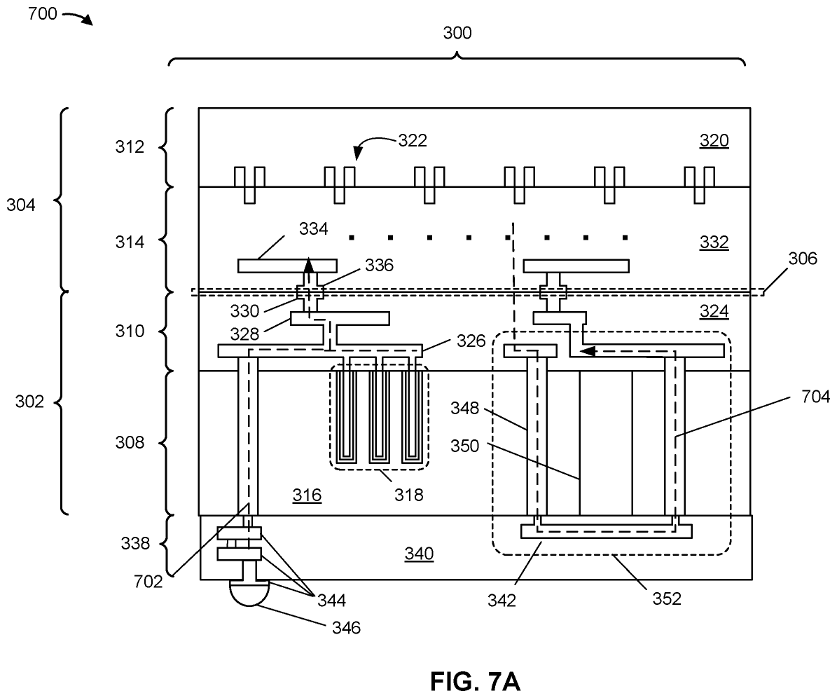

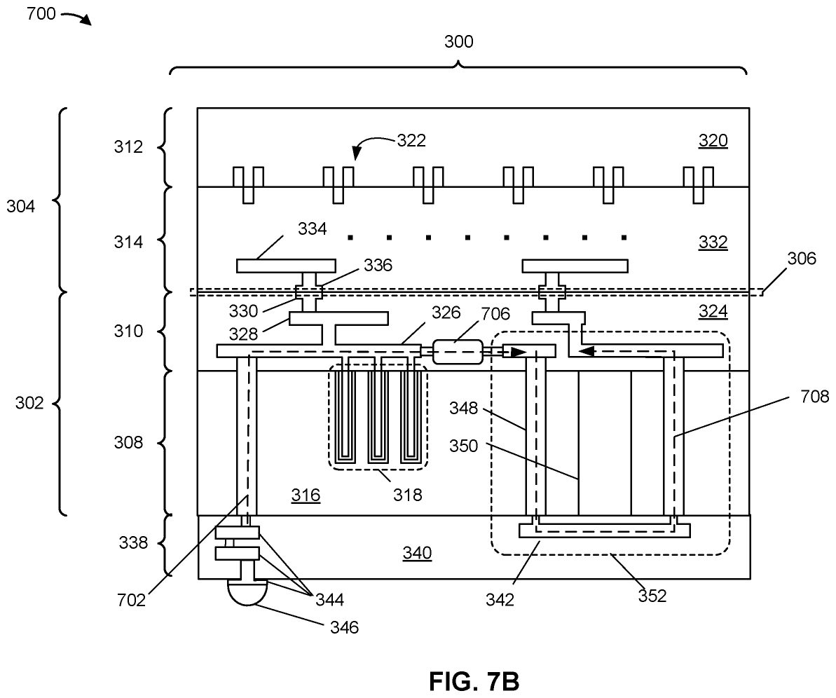

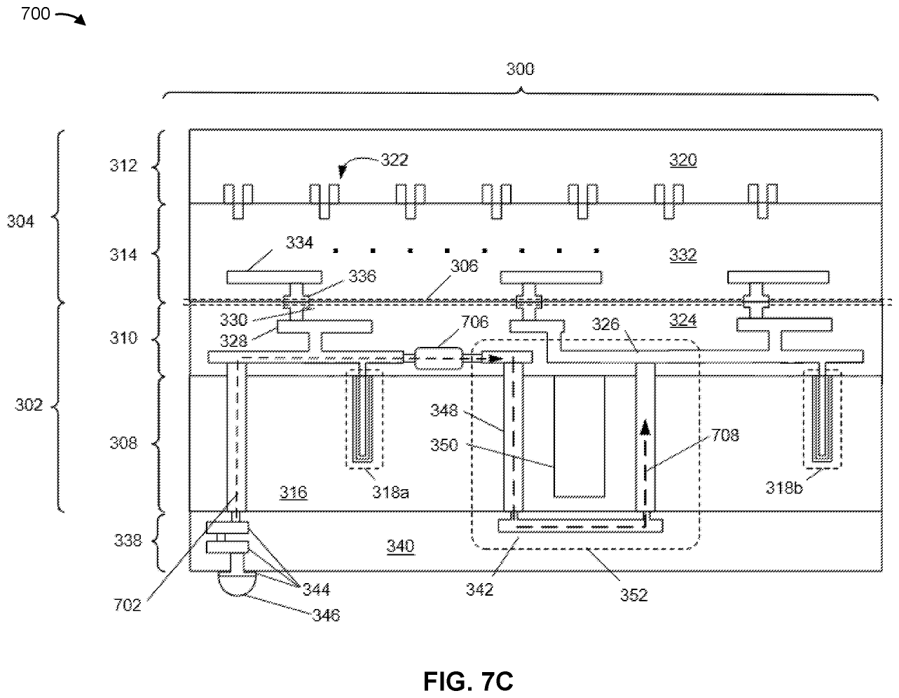

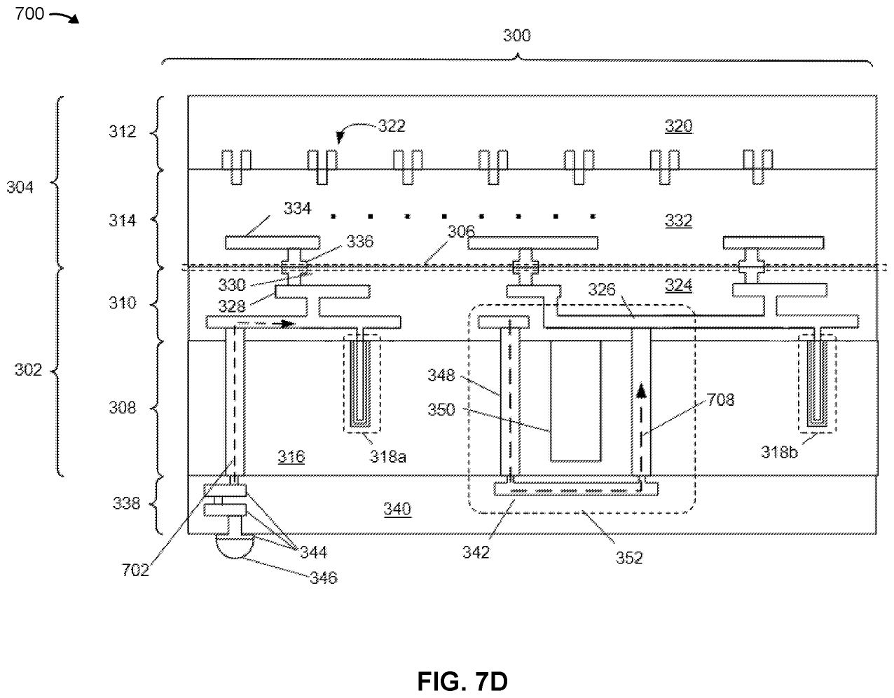

FIGS. 7A-7C are diagrams of example implementations 700 of circuits including an example solenoid inductor structure described herein. The solenoid inductor structure may correspond to the solenoid inductor structure 352.

As shown in FIG. 7A, the semiconductor die package may receive an input current 702 through the conductive terminal 346. In FIG. 7A, portions of the input current 702 may route to the trench capacitor structure 318. Additionally, or alternatively, portions of the input current 702 may route through the interconnect region 310, through the interconnect region 314, and to the device region 312 including the integrated circuit devices 322. Further, and as shown in FIG. 7A, an integrated circuit device output current 704 may be routed from the device region 312, through the interconnect region 314, through the interconnect region 310, and to the solenoid inductor structure 352.

In some implementations, and as shown in FIG. 7B, the semiconductor die package 300 may include a switching device 706, where one or more components of the switching device 706 are within the interconnect region 310. In such a case, and as shown in FIG. 7B, the semiconductor die package 300 may receive the input current 702 through the conductive terminal 346. As shown in FIG. 7B, portions of the input current 702 may route to the trench capacitor structure 318 and/or the switching device 706. Further, and as shown in FIG. 7B, a inductor current 708 may route from the from the switching device 706 to the solenoid inductor structure 352.

In some implementations, and as shown in FIG. 7C, the semiconductor die package 300 may include multiple trench capacitor structures (e.g., the trench capacitor structure 318a including a single trench capacitor and the trench capacitor structure 318b including a single trench capacitor). As shown in FIG. 7C, one or more components of the switching device 706 are within the interconnect region 310. Further, and as shown in FIG. 7C, the semiconductor die package 300 may receive the input current 702 through the conductive terminal 346. Portions of the input current 702 may route through the switching device 706. Further, and as shown in FIG. 7C, the inductor current 708 may route from the from the switching device 706, through the solenoid inductor structure 352, and to the metallization layer 326 and trench capacitor structure 318b.

In some implementations, and as shown in FIG. 7D, the semiconductor die package 300 may include multiple trench capacitor structures (e.g., the trench capacitor structure 318a including a single trench capacitor and the trench capacitor structure 318b including a single trench capacitor). In contrast to FIG. 7C, the interconnect region of FIG. 7D excludes the switching device 706. In such a case, the input current 702 and inductor current 708 may route to and from other types of devices included in the semiconductor die package 300 (the integrated circuit devices 322, among other examples) using other conductive structures within the semiconductor die package (e.g., the metallization layer 326, the metallization layer 328, the metallization layer 334, the contact 330, and/or the contact 336).

As indicated above, FIGS. 7A-7D are provided as examples. Other examples may differ from what is described with regard to FIGS. 7A-7D.

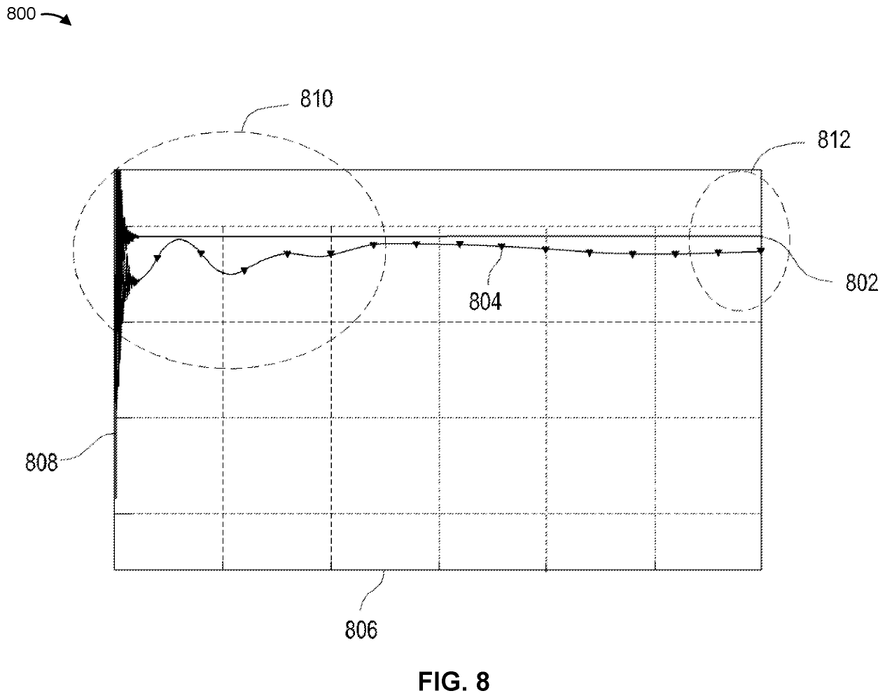

FIG. 8 is a diagram 800 including an example transient response of a semiconductor die package including the solenoid inductor structure described herein. In some implementations, the semiconductor die package corresponds to the semiconductor die package 300 and the solenoid inductor structure corresponds to the solenoid inductor structure 352.

The diagram 800 includes an input voltage 802 (e.g., a reference voltage in volts) and a response voltage 804 (e.g., a transient response in volts). The diagram 800 includes a time-based axis 806 and a voltage axis 808.

A first transient response 810 may correspond to a transient response of a device including a voltage regulator circuit (e.g., the voltage regulator circuit 200) that is separate from integrated circuitry. For example, the device having the first transient response 810 may include voltage regulator circuitry (e.g., an inductor component and a capacitor component) and integrated circuitry (e.g., an integrated circuit device component) in separate semiconductor die packages mounted to a printed circuit board (PCB).

In contrast, a second transient response 812 may correspond to a transient response of a device including a voltage regulator circuit (e.g., the voltage regulator circuit 200) and integrated circuitry that are both included in a same semiconductor die package (e.g., the semiconductor die package 300). The voltage regulator circuit may include a trench capacitor structure (e.g., the trench capacitor structure 318) and a solenoid inductor structure (e.g., the solenoid inductor structure 352).

As shown in FIG. 8, the second transient response 812 (e.g., corresponding to the semiconductor die package 300 including the trench capacitor structure 318 and the solenoid inductor structure 352) is dampened (e.g., improved) relative to the first transient response 810.

As indicated above, FIG. 8 is provided as an example. Other examples may differ from what is described with regards to FIG. 8.

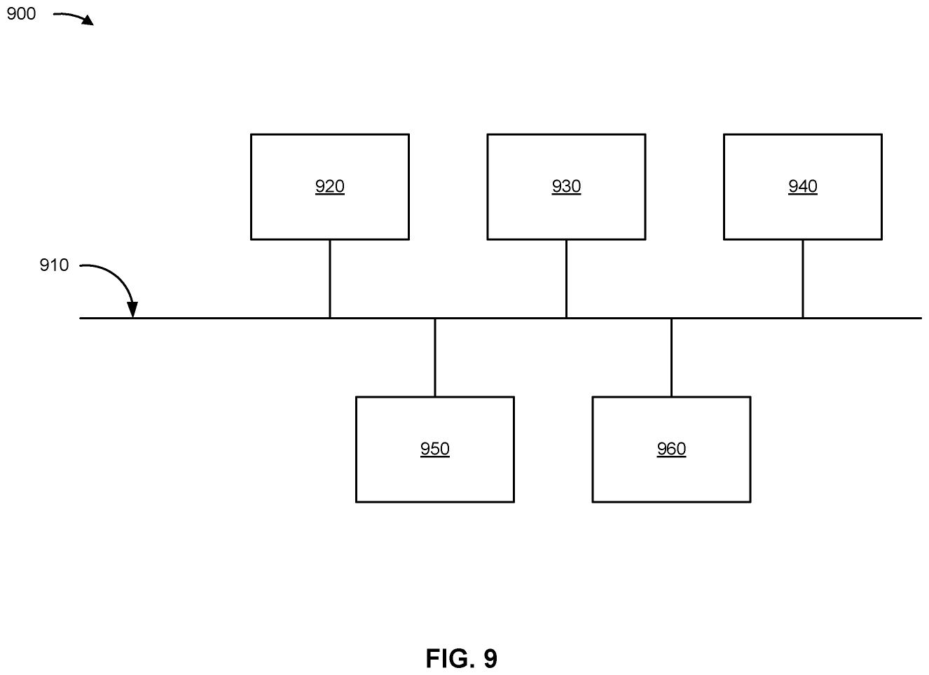

FIG. 9 is a diagram of example components of a device 900 associated with forming an inductor embedded in a substrate of a semiconductor device. The device 900 may correspond to one or more of the semiconductor processing tools 102-114 and/or the wafer/die transport tool 116. In some implementations, one or more of the semiconductor processing tools 102-116 and/or the wafer/die transport tool 116 may include one or more devices 900 and/or one or more components of the device 900. As shown in FIG. 9, the device 900 may include a bus 910, a processor 920, a memory 930, an input component 940, an output component 950, and/or a communication component 960.

The bus 910 may include one or more components that enable wired and/or wireless communication among the components of the device 900. The bus 910 may couple together two or more components of FIG. 9, such as via operative coupling, communicative coupling, electronic coupling, and/or electric coupling. For example, the bus 910 may include an electrical connection (e.g., a wire, a trace, and/or a lead) and/or a wireless bus. The processor 920 may include a central processing unit, a graphics processing unit, a microprocessor, a controller, a microcontroller, a digital signal processor, a field-programmable gate array, an application-specific integrated circuit, and/or another type of processing component. The processor 920 may be implemented in hardware, firmware, or a combination of hardware and software. In some implementations, the processor 920 may include one or more processors capable of being programmed to perform one or more operations or processes described elsewhere herein.

The memory 930 may include volatile and/or nonvolatile memory. For example, the memory 930 may include random access memory (RAM), read only memory (ROM), a hard disk drive, and/or another type of memory (e.g., a flash memory, a magnetic memory, and/or an optical memory). The memory 930 may include internal memory (e.g., RAM, ROM, or a hard disk drive) and/or removable memory (e.g., removable via a universal serial bus connection). The memory 930 may be a non-transitory computer-readable medium. The memory 930 may store information, one or more instructions, and/or software (e.g., one or more software applications) related to the operation of the device 900. In some implementations, the memory 930 may include one or more memories that are coupled (e.g., communicatively coupled) to one or more processors (e.g., processor 920), such as via the bus 910. Communicative coupling between a processor 920 and a memory 930 may enable the processor 920 to read and/or process information stored in the memory 930 and/or to store information in the memory 930.

The input component 940 may enable the device 900 to receive input, such as user input and/or sensed input. For example, the input component 940 may include a touch screen, a keyboard, a keypad, a mouse, a button, a microphone, a switch, a sensor, a global positioning system sensor, an accelerometer, a gyroscope, and/or an actuator. The output component 950 may enable the device 900 to provide output, such as via a display, a speaker, and/or a light-emitting diode. The communication component 960 may enable the device 900 to communicate with other devices via a wired connection and/or a wireless connection. For example, the communication component 960 may include a receiver, a transmitter, a transceiver, a modem, a network interface card, and/or an antenna.

The device 900 may perform one or more operations or processes described herein. For example, a non-transitory computer-readable medium (e.g., memory 930) may store a set of instructions (e.g., one or more instructions or code) for execution by the processor 920. The processor 920 may execute the set of instructions to perform one or more operations or processes described herein. In some implementations, execution of the set of instructions, by one or more processors 920, causes the one or more processors 920 and/or the device 900 to perform one or more operations or processes described herein. In some implementations, hardwired circuitry may be used instead of or in combination with the instructions to perform one or more operations or processes described herein. Additionally, or alternatively, the processor 920 may be configured to perform one or more operations or processes described herein. Thus, implementations described herein are not limited to any specific combination of hardware circuitry and software.

The number and arrangement of components shown in FIG. 9 are provided as an example. The device 900 may include additional components, fewer components, different components, or differently arranged components than those shown in FIG. 9. Additionally, or alternatively, a set of components (e.g., one or more components) of the device 900 may perform one or more functions described as being performed by another set of components of the device 900.

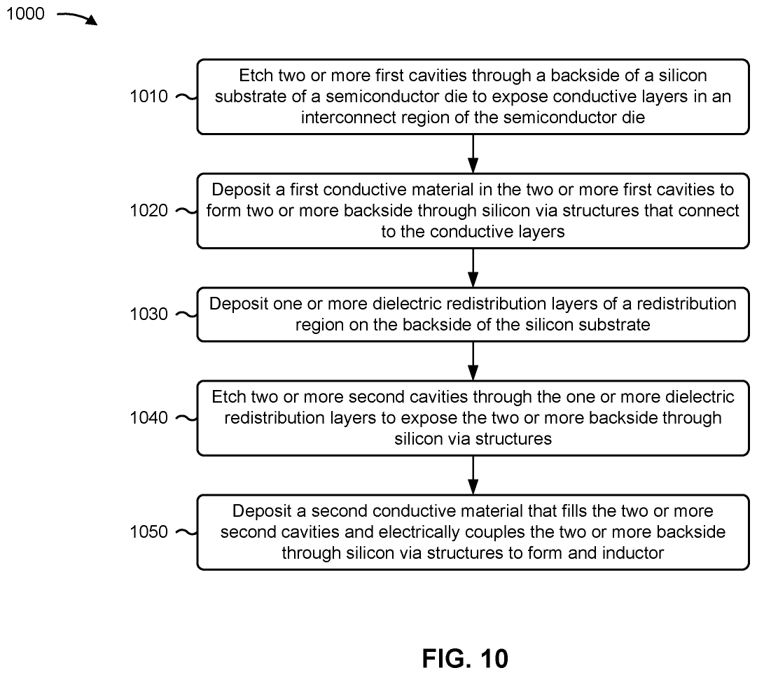

FIG. 10 is a flowchart of an example process 1000 associated with forming an inductor embedded in a substrate of a semiconductor device. In some implementations, one or more process blocks of FIG. 10 are performed by one or more semiconductor processing tools and/or a wafer/die transport tool (e.g., one or more of the semiconductor processing tools 102-114 and/or the wafer/die transport tool 116). Additionally, or alternatively, one or more process blocks of FIG. 10 may be performed by one or more components of device 900, such as processor 920, memory 930, input component 940, output component 950, and/or communication component 960.

As shown in FIG. 10, process 1000 may include etching two or more first cavities through a backside of a silicon substrate of a semiconductor die to expose conductive layers in an interconnect region of the semiconductor die (block 1010). For example, one or more of the semiconductor processing tools 102-114 (e.g., the etch tool 108) may etch two or more first cavities through a backside of a silicon substrate (e.g., the substrate 316) of a semiconductor die (e.g., the semiconductor die 302) to expose conductive layers (e.g., conductive layers including the metallization layer 326) in an interconnect region (e.g., the interconnect region 310) of the semiconductor die, as described herein.

As further shown in FIG. 10, process 1000 may include depositing a first conductive material in the two or more first cavities to form two or more backside through silicon via structures that connect to the conductive layers (block 1020). For example, one or more of the semiconductor processing tools 102-114 (e.g., the deposition tool 102) may deposit a first conductive material in the two or more first cavities to form two or more backside through silicon via structures (e.g., the BTSV structures 348) connect to the conductive layers, as described herein.

As further shown in FIG. 10, process 1000 may include depositing one or more dielectric redistribution layers of a redistribution region on the backside of the silicon substrate (block 1030). For example, one or more of the semiconductor processing tools 102-114 (e.g., the deposition tool 102) may deposit one or more dielectric redistribution layers (e.g., the dielectric layers 340) of a redistribution region (e.g., the redistribution region 338) on the backside of the silicon substrate, as described herein.

As further shown in FIG. 10, process 1000 may include etching two or more second cavities through the one or more dielectric redistribution layers to expose the two or more backside through silicon via structures (block 1040). For example, one or more of the semiconductor processing tools 102-114 may etch two or more second cavities through the one or more dielectric redistribution layers to expose the two or more backside through silicon via structures, as described herein.

As further shown in FIG. 10, process 1000 may include depositing a second conductive material that fills the two or more second cavities and electrically couples the two or more backside through silicon via structures to form and inductor (block 1050). For example, one or more of the semiconductor processing tools 102-114 may deposit a second conductive material (e.g., the one or more metallization layers 342) that fills the two or more second cavities and electrically couples the two or more backside through silicon via structures to form and inductor (e.g., the solenoid inductor structure 352), as described herein.

Process 1000 may include additional implementations, such as any single implementation or any combination of implementations described below and/or in connection with one or more other processes described elsewhere herein.

In a first implementation, depositing the second conductive material that fills the two or more second cavities and electrically couples the two or more backside through silicon via structures to form the inductor comprises electrically coupling the conductive layers and the two or more backside through silicon via structures to form a solenoid inductor structure within the semiconductor die that spans the interconnect region, the silicon substrate, and the redistribution region of the semiconductor die.

In a second implementation, alone or in combination with the first implementation, the semiconductor die is a first semiconductor die and further includes joining the first semiconductor die with a second semiconductor die (e.g., the semiconductor die 304).

In a third implementation, alone or in combination with one or more of the first and second implementations, joining the first semiconductor die with the second semiconductor die includes joining surfaces of metal contacts of the first semiconductor die and the second semiconductor die (e.g., the contacts 330 and 336).

In a fourth implementation, alone or in combination with one or more of the first through third implementations, joining the first semiconductor die with the second semiconductor die includes joining surfaces of dielectric layers of the first semiconductor die and the second semiconductor die (e.g., surfaces of the one or more dielectric layers 324 and 332).

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

Some implementations described herein provide an inductor device formed in a substrate of a semiconductor device including an integrated circuit device. The inductor device may use one or more conduction layers that are included in the substrate. Furthermore, the inductor device may be electrically coupled to the integrated circuit device. By forming the inductor device in the substrate of the semiconductor device, an electrical circuit including the inductor device and the integrated circuit device may be formed within a single semiconductor device.

In this way, and relative to an implementation of the electrical circuit that uses a discrete inductor device, a length of an electrical path between the inductor device and the integrated circuit device may be reduced to increase a performance of the electrical circuit. Additionally, or alternatively, the inclusion of the inductor device within the semiconductor device may eliminate a need for a separate semiconductor die package (for the discrete inductor device) to reduce an amount of resources used to form the electrical circuit (semiconductor processing tools, raw materials, manpower, and/or computing resources, among other examples).

As described in greater detail above, some implementations described herein provide a semiconductor die package. The semiconductor die package includes a substrate region including a first side and a second side opposite the first side. The semiconductor die package includes an interconnect region over the first side of the substrate region comprising at least one metal layer. The semiconductor die package includes a redistribution region over the second side of the substrate region comprising at least one conductive layer. The semiconductor die package includes at least two via structures passing through the substrate region connecting the conductive layer in the redistribution region and the at least one metal layer in the interconnect region, where the at least two via structures, the conductive layer, and the metal layer form an inductor.

As described in greater detail above, some implementations described herein provide a semiconductor die package. The semiconductor die package includes a first semiconductor die including a substrate region, an interconnect region over the substrate region, a via structure passing through the substrate region, and an inductor including a portion formed in the substrate region. The semiconductor die package includes a second semiconductor die bonded to the interconnect region of the first semiconductor die.

As described in greater detail above, some implementations described herein provide a method. The method includes etching two or more first cavities through a backside of a silicon substrate of a semiconductor die to expose conductive layers in an interconnect region of the semiconductor die. The method includes depositing a first conductive material in the two or more first cavities to form two or more backside through silicon via structures that connect to the conductive layers. The method includes depositing one or more dielectric redistribution layers of a redistribution region on the backside of the silicon substrate. The method includes etching two or more second cavities through the one or more dielectric redistribution layers to expose the two or more backside through silicon via structures. The method includes depositing a second conductive material that fills the two or more second cavities and electrically couples the two or more backside through silicon via structures to form and inductor.

As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor die package, comprising:
a substrate region including a first side and a second side opposite the first side;
an interconnect region over the first side of the substrate region comprising at least one metal layer;
a redistribution region over the second side of the substrate region comprising at least one conductive layer; and
at least two via structures passing through the substrate region connecting the conductive layer in the redistribution region and the at least one metal layer in the interconnect region,
wherein the at least two via structures, the conductive layer, and the metal layer form an inductor.

2. The semiconductor die package of claim 1, wherein the inductor comprises:
an approximately helical shaped structure dispersed along an approximately lateral axis within the substrate region.

3. The semiconductor die package of claim 1, wherein the inductor comprises:
an approximately toroidal shaped structure centered about an approximately vertical axis within the substrate region.

4. The semiconductor die package of claim 1, wherein the inductor comprises:
an inverse coupled structure comprising:
a first portion configured to conduct a first electrical current along a first approximately helical path in a first direction; and
a second portion configured to conduct a second electrical current along a second approximately helical path in a second direction that is opposite the first direction.

5. The semiconductor die package of claim 1, wherein the inductor comprises:
a portion of a first conductive layer within the interconnect region,
two or more interconnect structures within the substrate region, and
a portion of a second conductive layer within the redistribution region.

6. The semiconductor die package of claim 5, wherein the inductor further comprises:
a magnetic core structure within the substrate region between the two or more interconnect structures.

7. The semiconductor die package of claim 5, wherein the inductor further comprises:
a shunting structure.

8. The semiconductor die package of claim 7, wherein the shunting structure comprises:
interconnect structures of the two or more interconnect structures within the substrate region.

9. The semiconductor die package of claim 7, wherein the shunting structure comprises:
portions of two or more conductive layers within the interconnect region.

10. A semiconductor die package, comprising:
a first semiconductor die comprising:
a substrate region;
an interconnect region over the substrate region;
a via structure passing through the substrate region; and
an inductor including a portion formed in the substrate region; and
a second semiconductor die bonded to the interconnect region of the first semiconductor die.

11. The semiconductor die package of claim 10, wherein the first semiconductor die further comprises:
a trench capacitor structure, and
a switching device that connects the trench capacitor structure and the inductor.

12. The semiconductor die package of claim 10, wherein the second semiconductor die comprises:
logic circuitry.

13. The semiconductor die package of claim 10, wherein an inductance performance of the inductor is included in a range of approximately 0.1 nanohenrys to approximately 100 nanohenrys.

14. The semiconductor die package of claim 10, wherein the first semiconductor die further comprises:
a redistribution region, and
wherein the inductor comprises:
another portion within the redistribution region.

15. The semiconductor die package of claim 14, wherein the via structure is a first via structure and the inductor further comprises:
a magnetic core structure between the first via structure and a second via structure.

16. A method, comprising:
etching two or more first cavities through a backside of a silicon substrate of a semiconductor die to expose conductive layers in an interconnect region of the semiconductor die;
depositing a first conductive material in the two or more first cavities to form two or more backside through silicon via structures that connect to the conductive layers;
depositing one or more dielectric redistribution layers of a redistribution region on the backside of the silicon substrate;
etching two or more second cavities through the one or more dielectric redistribution layers to expose the two or more backside through silicon via structures; and
depositing a second conductive material that fills the two or more second cavities and electrically couples the two or more backside through silicon via structures to form and inductor.

17. The method of claim 16, wherein depositing the second conductive material that fills the two or more second cavities and electrically couples the two or more backside through silicon via structures to form the inductor comprises:
electrically coupling the conductive layers and the two or more backside through silicon via structures to form a solenoid inductor structure within the semiconductor die that spans the interconnect region, the silicon substrate, and the redistribution region of the semiconductor die.

18. The method of claim 16, wherein the semiconductor die is a first semiconductor die and further comprising:
joining the first semiconductor die with a second semiconductor die.

19. The method of claim 18, wherein joining the first semiconductor die with the second semiconductor die comprises:
joining surfaces of metal contacts of the first semiconductor die and the second semiconductor die.

20. The method of claim 19, wherein joining the first semiconductor die with the second semiconductor die further comprises:
joining surfaces of dielectric layers of the first semiconductor die and the second semiconductor die.
